(19) United States
(12) Patent Application Publication
(10) Pub. No.: US 2022/0199476 A1
(43) Pub. Date: Jun. 23, 2022

(54) SEMICONDUCTOR DEVICE, METHOD FOR MANUFACTURING SEMICONDUCTOR DEVICE, AND POWER CONVERSION DEVICE

(71) Applicant: Mitsubishi Electric Corporation, Chiyoda-ku, Tokyo (JP)

(72) Inventor: Ryuichiro HANADA, Chiyoda-ku, Tokyo (JP)

(73) Assignee: Mitsubishi Electric Corporation, Chiyoda-ku, Tokyo (JP)

(21) Appl. No.: 17/606,054

(22) PCT Filed: Jul. 2, 2019
(86) PCT No.: PCT/JP2019/026306

§ 371 Date: Oct. 25, 2021

(51) Int. Cl. H01L 23/12; H01L 23/29; H01L 23/04; H01L 23/18; H01L 23/31; H01L 23/367; H01L 23/40; H01L 25/07; H01L 23/00

(52) U.S. Cl. CPC H01L 23/12; H01L 23/29; H01L 23/04; H01L 23/18; H01L 23/3121; H01L 2224/05099; H01L 23/40; H01L 25/072; H01L 24/05; H01L 2924/35121; H01L 23/367

(57) ABSTRACT

Peeling of a bonding material is prevented at a bonding portion between a base plate and an insulating substrate due to thermal stress to obtain a semiconductor device with improved reliability. The semiconductor device includes: a base plate; an insulating substrate including an insulating layer and is provided with metal layers on an upper surface and a lower surface of the insulating layer; a bonding material that bonds an upper surface of the base plate and a lower surface of the metal layer on a lower surface-side of the insulating layer; a case member that is disposed on the upper surface of the base plate to surround the insulating substrate; and a pressing member that is disposed in a region surrounded by the base plate and the case member, and is in contact with the upper surface of the insulating substrate while straddling facing sides of the insulating substrate.

### TECHNICAL FIELD

The present invention relates to a semiconductor device including a peeling prevention structure at a bonding portion between a base plate and an insulating substrate, a method for manufacturing the semiconductor device, and a power conversion device.

### BACKGROUND ART

The semiconductor device includes a semiconductor element, and the semiconductor element generates heat by energizing the semiconductor device. The heat generation is dissipated from the semiconductor element toward the base plate. By repeating the energization to the semiconductor device, thermal stress is generated in constituent members of the semiconductor device due to a difference in linear expansion coefficient, and damage such as a crack, a void, or peeling is generated between the constituent members.

In particular, the damage is generated in a bonding material among the constituent members. When the bonding material bonding the base plate and the insulating substrate is damaged, the heat dissipation of the heat generated in the semiconductor element is degraded. When a heat dissipation property degrades, a temperature of the semiconductor element rises, a lifetime of the wiring member or the like bonded onto the semiconductor element is decreased, and reliability of the semiconductor device is lowered. Consequently, when the damage due to the thermal stress of the bonding material between the base plate and the insulating substrate can be decreased, the degradation of the heat dissipation can be prevented.

For this reason, in order to solve this problem, a semiconductor device including a case outer frame having a protrusion in contact with an internal circuit board on which a semiconductor element is mounted is disclosed (for example, PTL 1). In addition, a semiconductor device including an outer case in which an elastic biasing member is disposed on a chip mounting substrate and that is in contact with the elastic biasing member is disclosed (for example, PTL 2). Furthermore, a semiconductor device including a heat sink, a frame, a leaf spring that protrudes from the heat sink and is in contact with the frame, and a substrate that is in contact with the frame is disclosed (for example, PTL 3).

### CITATION LIST

### Patent Literature

PTL 1: Japanese Patent Laying-Open No. 62-007145

PTL 2: Japanese Patent Laying-Open No. 11-330328

PTL 3: Japanese Patent Laying-Open No. 2000-299419

### SUMMARY OF INVENTION

### Technical Problem

However, in the conventional protrusion described in PTL 1, because only the outer peripheral portion of the internal circuit board is pressed, the degradation of the outer peripheral portion of an internal circuit board lower adhesive can be decreased, but the degradation of a central portion of the internal circuit board cannot be decreased, and sometimes the reliability of the semiconductor device is degraded. In addition, in the conventional elastic biasing member described in PTL 2, because only the outer peripheral portion of the chip mounting substrate is pressed, the degradation of the outer peripheral portion of the chip mounting substrate can be decreased, but the degradation of the central portion of the chip mounting substrate cannot be decreased, and sometimes the reliability of the semiconductor device is degraded. Furthermore, in the conventional leaf spring described in PTL 3, because the peripheral portion of the frame is pressed, the degradation of the substrate lower peripheral portion can be decreased, but the degradation of the substrate lower central portion cannot be decreased, and sometimes the reliability of the semiconductor device is degraded.

The present invention has been made to solve the above-described problems, and an object of the present invention is to obtain a semiconductor device with improved reliability by preventing the peeling of the bonding material at the bonding portion between the base plate and the insulating substrate due to the thermal stress.

### Solution to Problem

In one aspect of the present invention, a semiconductor device including: a base plate; an insulating substrate including an insulating layer, and metal layers provided on an upper surface and a lower surface of the insulating layer; a bonding material configured to bond an upper surface of the base plate and a lower surface of the metal layer on a lower surface-side of the insulating layer; a case member disposed on the upper surface of the base plate to surround the insulating substrate; and a pressing member that is disposed in a region surrounded by the base plate and the case member, and is in contact with an upper surface of the insulating substrate while straddling facing sides of the insulating substrate.

### Advantageous Effects of Invention

According to the present invention, because the pressing member in contact with the upper surface of the insulating substrate while straddling the facing sides of the insulating substrate is provided, the bonding material bonding the base plate and the insulating substrate is pressed in the direction of the base plate, the damage to the bonding material can be prevented, and the reliability of the semiconductor device can be improved.

### BRIEF DESCRIPTION OF DRAWINGS

FIG. 1 is a planar structure schematic diagram illustrating a semiconductor device according to a first embodiment of the present invention.

FIG. 2 is a sectional structure schematic diagram illustrating the semiconductor device of the first embodiment of the present invention.

FIG. 3 is another sectional structure schematic diagram illustrating the semiconductor device of the first embodiment of the present invention.

FIG. 4 is a sectional structure schematic diagram illustrating a pressing member in the semiconductor device of the first embodiment of the present invention.

FIG. 5 is a sectional structure schematic diagram illustrating another pressing member in the semiconductor device of the first embodiment of the present invention.

FIG. 6 is a sectional structure schematic diagram illustrating another pressing member in the semiconductor device of the first embodiment of the present invention.

FIG. 7 is a sectional structure schematic diagram illustrating another pressing member in the semiconductor device of the first embodiment of the present invention.

FIG. 8 is a sectional structure schematic diagram illustrating another semiconductor device of the first embodiment of the present invention.

FIG. 9 is a sectional structure schematic diagram illustrating another semiconductor device of the first embodiment of the present invention.

FIG. 10 is a sectional structure schematic diagram illustrating another semiconductor device of the first embodiment of the present invention.

FIG. 11 is a sectional structure schematic diagram illustrating another semiconductor device of the first embodiment of the present invention.

FIG. 12 is a planar structure schematic diagram illustrating another semiconductor device of the first embodiment of the present invention.

FIG. 13 is a planar structure schematic diagram illustrating another semiconductor device of the first embodiment of the present invention.

FIG. 14 is a planar structure schematic diagram illustrating another semiconductor device of the first embodiment of the present invention.

FIG. 15 is a sectional structure schematic diagram illustrating another semiconductor device of the first embodiment of the present invention.

FIG. 16 is a planar structure schematic diagram illustrating a semiconductor device according to a second embodiment of the present invention.

FIG. 17 is a sectional structure schematic diagram illustrating the semiconductor device of the second embodiment of the present invention.

FIG. 18 is a planar structure schematic diagram illustrating another semiconductor device of the second embodiment of the present invention.

FIG. 19 is a planar structure schematic diagram illustrating another semiconductor device of the second embodiment of the present invention.

FIG. 20 is a planar structure schematic diagram illustrating another semiconductor device of the second embodiment of the present invention.

FIG. 21 is a sectional structure schematic diagram illustrating another semiconductor device of the second embodiment of the present invention.

FIG. 22 is a planar structure schematic diagram illustrating a semiconductor device according to a third embodiment of the present invention.

FIG. 23 is a planar structure schematic diagram illustrating the semiconductor device of the third embodiment of the present invention.

FIG. 24 is a sectional structure schematic diagram illustrating another semiconductor device of the third embodiment of the present invention.

FIG. 25 is a sectional structure schematic diagram illustrating another semiconductor device of the third embodiment of the present invention.

FIG. 26 is a sectional structure schematic diagram illustrating another semiconductor device of the third embodiment of the present invention.

FIG. 27 is a planar structure schematic diagram illustrating another semiconductor device of the third embodiment of the present invention.

FIG. 28 is a planar structure schematic diagram illustrating another semiconductor device of the third embodiment of the present invention.

FIG. 29 is a planar structure schematic diagram illustrating another semiconductor device of the third embodiment of the present invention.

FIG. 30 is a sectional structure schematic diagram illustrating another semiconductor device of the third embodiment of the present invention.

FIG. 31 is a planar structure schematic diagram illustrating a semiconductor device according to a fourth embodiment of the present invention.

FIG. 32 is a sectional structure schematic diagram illustrating the semiconductor device of the fourth embodiment of the present invention.

FIG. 33 is a planar structure schematic diagram illustrating another semiconductor device of the fourth embodiment of the present invention.

FIG. 34 is a planar structure schematic diagram illustrating another semiconductor device of the fourth embodiment of the present invention.

FIG. 35 is a planar structure schematic diagram illustrating another semiconductor device of the fourth embodiment of the present invention.

FIG. 36 is a sectional structure schematic diagram illustrating another semiconductor device of the fourth embodiment of the present invention.

FIG. 37 is a planar structure schematic diagram illustrating a semiconductor device according to a fifth embodiment of the present invention.

FIG. 38 is a sectional structure schematic diagram illustrating the semiconductor device of the fifth embodiment of the present invention.

FIG. 39 is a planar structure schematic diagram illustrating another semiconductor device of the fifth embodiment of the present invention.

FIG. 40 is a sectional structure schematic diagram illustrating another semiconductor device of the fifth embodiment of the present invention.

FIG. 41 is a planar structure schematic diagram illustrating another semiconductor device of the fifth embodiment of the present invention.

FIG. 42 is a sectional structure schematic diagram illustrating another semiconductor device of the fifth embodiment of the present invention.

FIG. 43 is a planar structure schematic diagram illustrating another semiconductor device of the fifth embodiment of the present invention.

FIG. 44 is a sectional structure schematic diagram illustrating another semiconductor device of the fifth embodiment of the present invention.

FIG. 45 is a block diagram illustrating a configuration of a power conversion system to which a power conversion device according to a sixth embodiment of the present invention is applied.

### DESCRIPTION OF EMBODIMENTS

With reference to the drawings, an overall configuration of a semiconductor device of the present invention will be described. It should be noted that the drawings are schematic but do not reflect exact sizes of illustrated components. In addition, those denoted with the same reference numerals are the same or equivalent thereto, and this is common in the entire specification.

### First Embodiment

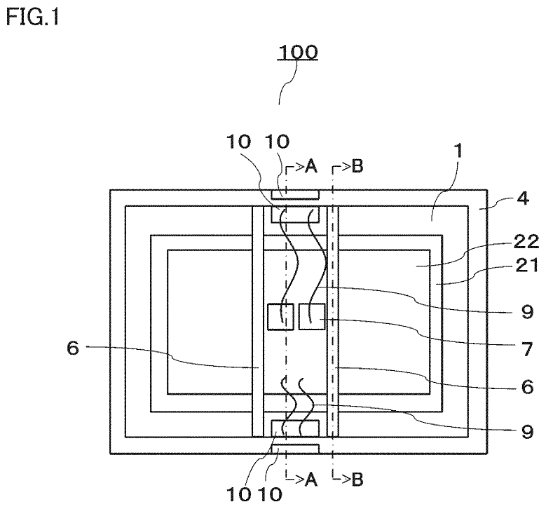

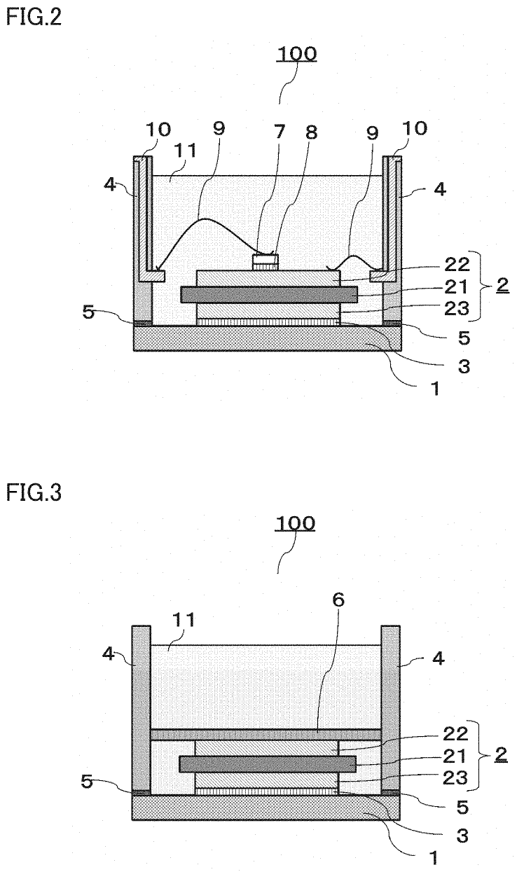

FIG. 1 is a planar structure schematic diagram illustrating a semiconductor device according to a first embodiment of the present invention. FIG. 2 is a sectional structure schematic diagram illustrating the semiconductor device of the first embodiment of the present invention. FIG. 3 is another sectional structure schematic diagram illustrating the semiconductor device of the first embodiment of the present invention. FIG. 1 is a planar structure schematic diagram of a semiconductor device 100 when viewed from above. FIG. 2 is a sectional structure schematic diagram taken along an alternate long and short dash line AA in FIG. 1. FIG. 3 is a sectional structure schematic diagram taken along an alternate long and short dash line BB in FIG. 1.

In the drawing, semiconductor device 100 includes a base plate 1, an insulating substrate 2, an insulating substrate lower bonding material 3 which is a bonding material, a case member 4, an adhesive 5, a pressing member 6, a semiconductor element 7, a semiconductor element lower bonding material 8, a wiring member 9, a terminal 10, and a filling member 11.

In the drawing, semiconductor device 100 includes base plate 1, insulating substrate 2 bonded to an upper surface of base plate 1 by insulating substrate lower bonding material 3, case member 4 that is formed on the upper surface of base plate 1 so as to surround insulating substrate 2 and bonded to insulating substrate 2 by adhesive 5, semiconductor element 7 bonded to a surface of insulating substrate 2 opposite to base plate 1 by semiconductor element lower bonding material 8, and pressing member 6 that presses semiconductor element 7 from the upper surface of semiconductor element 7 opposite to insulating substrate 2 toward base plate 1.

Insulating substrate 2 includes an upper surface and a lower surface. The lower surface of insulating substrate 2 faces the upper surface of base plate 1. Insulating substrate 2 includes an insulating layer 21, and insulating layer 21 includes an upper surface and a lower surface. In insulating substrate 2, a metal layer 22 is formed on the upper surface of insulating layer 21, and a metal layer 23 is formed on the lower surface of insulating layer 21. Metal layer 23 on the lower surface-side of insulating layer 21 is bonded to the upper surface of base plate 1 by insulating substrate lower bonding material 3. Insulating substrate 2 has a plate shape, and when plate-shaped insulating substrate 2 is viewed from a planar direction, the sizes of metal layers 22, 23 are smaller than the size of insulating layer 21 in order that metal layer 22 prevents creeping discharge (secure a creeping distance) between metal layer 23 and base plate 1 with insulating layer 21 interposed therebetween. Metal layer 22 on the upper surface-side of insulating layer 21 may be divided into a plurality of parts according to the purpose to form a circuit pattern. Aluminum oxide (Al₂O₃), aluminum nitride (AlN), silicon nitride (Si3N₄), or the like can be used as a material of insulating layer 21 of insulating substrate 2. A copper alloy, an aluminum alloy, or the like can be used as a material of metal layers 22, 23 of insulating substrate 2. Semiconductor element 7 is bonded to an upper surface of metal layer 22 of insulating substrate 2 by semiconductor element lower bonding material 8.

Base plate 1 has a plate shape and is a bottom surface (bottom plate) of semiconductor device 100. Base plate 1 functions as a heat dissipation member that dissipates heat generated inside semiconductor device 100 to the outside of semiconductor device 100. In base plate 1, the upper surface of base plate 1 is bonded to the lower surface of metal layer 23 on the lower surface-side of insulating substrate 2 with (using) insulating substrate lower bonding material 3 interposed between base plate 1 and metal layer 23. A copper alloy, an aluminum alloy, or the like can be used as a material of base plate 1.

Insulating substrate lower bonding material 3 is a bonding material that bonds base plate 1 and insulating substrate 2. Solder is used as a material of insulating substrate lower bonding material 3, and sintered silver, sintered copper, or the like may be used as necessary.

Case member 4 is an outer frame body of semiconductor device 100. Insulating substrate 2 is bonded to a central region of base plate 1, and case member 4 is bonded to base plate 1 with adhesive 5 in an outer peripheral region of base plate 1 surrounding insulating substrate 2. Case member 4 is required to maintain an insulating property without causing thermal deformation in a use temperature range of semiconductor device 100. For this reason, a Poly Phenylene Sulfide (PPS) resin or a Poly Butylene Terephtalate (PBT) resin can be used as a material of case member 4.

Adhesive 5 bonds the upper surface of base plate 1 and the bottom surface of case member 4. A silicone resin, an epoxy resin, or the like is generally used as a material of adhesive 5, adhesive 5 is applied to at least one of case member 4 and base plate 1 to fix case member 4 and base plate 1, and then case member 4 and base plate 1 are bonded to each other by thermal curing.

Semiconductor element lower bonding material 8 is a bonding material that bonds the upper surface of metal layer 22 on the upper surface-side of insulating substrate 2 and semiconductor element 7. Similarly to insulating substrate lower bonding material 3, solder, sintered silver, sintered copper, or the like can be used as the material of semiconductor element lower bonding material 8.

Wiring member 9 electrically connects semiconductor element 7 and terminal 10. Wiring member 9 electrically connects metal layer 22 on the upper surface-side of insulating substrate 2 and terminal 10. When a plurality of semiconductor elements 7 are used, the plurality of semiconductor elements 7 are electrically connected to each other by wiring member 9. An aluminum alloy wire, a copper alloy wire, a copper alloy lead, an aluminum alloy ribbon, a copper alloy ribbon, or the like can be used as wiring member 9.

Terminal 10 electrically connects the inside of semiconductor device 100 and the outside of semiconductor device 100. Terminal 10 is used to supply power to semiconductor element 7 from the outside of semiconductor device 100 or to supply a drive signal to semiconductor element 7. A copper alloy or the like can be used as a material of terminal 10. Terminal 10 may be an insert type built in case member 4 or an outsert type provided in contact with an inner peripheral surface (inner wall) side of case member 4. In addition, terminal 10 may be disposed inside case member 4 in order to be connected to the outside corresponding to the wiring pattern formed by metal layer 22.

Semiconductor element 7 is bonded to the upper surface of metal layer 22 on the upper surface-side of insulating substrate 2 with semiconductor element lower bonding material 8, which is a bonding material, interposed between semiconductor element 7 and metal layer 22. A power semiconductor element such as a metal oxide semiconductor field effect transistor (MOSFET) and an insulated gate bipolar transistor (IGBT) can be used as semiconductor element 7. Silicon (Si), silicon cabide (SiC), or the like can be used as a material of semiconductor element.

Filling member 11 is filled in a region surrounded by case member 4 and base plate 1 for the purpose of securing an insulating property inside semiconductor device 100. Filling member 11 seals insulating substrate 2 (insulating layer 21 and metal layers 22, 23), pressing member 6, semiconductor element 7, and wiring member 9. For example, a silicone resin is used as filling member 11, but filling member 11 is not limited to the silicone resin, and any material having a desired elastic modulus, heat resistance, and adhesiveness may be used. For example, an epoxy resin, a urethane resin, a polyimide resin, a polyamide resin, an acrylic resin, or the like may be used as a material of filling member 11, or a resin material in which ceramic powders are dispersed may be used in order to enhance strength and heat dissipation.

In FIGS. 1 and 3, pressing member 6 presses insulating substrate 2 toward the upper surface-side (direction) of base plate 1. For example, pressing member 6 has a belt shape (rectangular shape) and has a long side and a short side. Pressing member 6 is in contact with the upper surface of insulating substrate 2 such that the long side direction straddles facing sides of metal layer 22 (insulating substrate 2) near semiconductor element 7 (traverses the facing sides). In the first embodiment, pressing member 6 is in contact with the upper surface of metal layer 22 on the upper surface-side of insulating substrate 2. Pressing member 6 continuously (integrally) straddles the facing sides of insulating substrate 2. The lower surface of pressing member 6 is in direct contact with the upper surface of metal layer 22. Pressing member 6 is disposed in contact with the inner peripheral surface of case member 4 or protruding inward from the inner peripheral surface. When pressing member 6 is disposed so as to continuously straddle the facing sides of insulating substrate 2, a pressing force to the direction of base plate 1 can be uniformly generated with respect to substrate lower bonding material 3 through insulating substrate 2. In addition, a plurality of pressing members 6 may be disposed, and each of the pressing members 6 straddles one of the facing sides of insulating substrate 2 from the outside to the inside in a planar view, is in contact with the upper surface of insulating substrate 2, and is disposed so as to straddle the other facing side of insulating substrate 2 from the inside to the outside.

Because metal layer 22 on the upper surface-side of insulating substrate 2 is a portion (member) through which current flows, a region (lower surface-side) in contact with pressing member 6 or pressing member 6 itself is desirably electrically insulated, and an insulator can be used as a material of pressing member 6. However, a metal member may be used as pressing member 6 as long as a portion in contact with the upper surface of metal layer 22 is insulated. An elastic body may be used as pressing member 6. When the elastic body is used as pressing member 6, pressing member 6 is pressed against the upper surface of metal layer 22 and elastically deformed, so that the contact area with metal layer 22 increases, and the pressing force can be uniformly applied. For example, rubber, resin, fiber, or the like can be used as the elastic body.

The same material as that of case member 4 can be used as the resin. When pressing member 6 is made of resin, pressing member 6 is a resin member harder than filling member 11 that is a resin member. Furthermore, using a material having good thermal conductivity as pressing member 6, heat can be dissipated not only from the side of base plate 1 but also from the upper surface-side of pressing member 6, and thermal stress on insulating substrate lower bonding material 3 can be reduced.

For example, a thickness of pressing member 6 ranges from about 100 μm to about 1000 μm. When the thickness of pressing member 6 is thin (less than 100 μm), strength of pressing member 6 cannot be obtained when insulating substrate 2 is pressed by pressing member 6, and sometimes pressing member 6 itself is damaged. In addition, when the thickness of pressing member 6 is large (1000 μm or more), the pressing force can be applied to insulating substrate 2, but pressing member 6 is hardly deformed. Therefore, pressing member 6 cannot correspond to the shape of insulating substrate 2, and sometimes the pressing force cannot be uniformly applied. In addition, when pressing member 6 is disposed below wiring member 9, it is necessary to increase a loop height of wiring member 9, which makes it difficult to dispose pressing member 6. Accordingly, the thickness of pressing member 6 may be a thickness of about 100 μm to 1000 μm, which is the thickness that can be appropriately deformed. A width of pressing member 6 may be any width as long as semiconductor element 7 or wiring member 9 disposed on the upper surface of metal layer 22 can be disposed.

As described above, because pressing member 6 is disposed in contact with the upper surface of metal layer 22 while straddling the facing sides of metal layer 22, entire metal layer 22 is pressed in the direction (thickness direction) of base plate 1, and compressive stress is generated in the entire inside of insulating substrate lower bonding material 3. As a result, generation and development of a crack in insulating substrate lower bonding material 3, or peeling between insulating substrate lower bonding material 3 and base plate 1 or insulating substrate 2 is prevented, so that the damage due to the thermal stress of insulating substrate lower bonding material 3 can be reduced and the reliability of semiconductor device 100 can be improved.

A method for manufacturing semiconductor device 100 of the first embodiment configured as described above will be described below.

First, base plate 1 that becomes the bottom surface of semiconductor device 100 is prepared (base plate preparation step).

Subsequently, insulating substrate 2 in which metal layers 22, 23 are provided on the upper surface and lower surface of the insulating layer 21 is prepared (insulating substrate preparing step). Insulating layer 21 and metal layers 22, 23 are bonded by brazing or the like. Because an electric circuit is formed in each of metal layers 22, 23, pattern shapes are often different. In such a case, the generation of the thermal stress may be prevented between the upper and lower (face and back) surfaces of insulating layer 21 by adjusting the size and thickness of metal layers 22, 23.

Subsequently, semiconductor element 7 is bonded to the upper surface of metal layer 22 on the upper surface-side of insulating substrate 2 using semiconductor element lower bonding material 8 (semiconductor element bonding step). After semiconductor element 7 is bonded to the upper surface of metal layer 22 on the upper surface-side of insulating substrate 2, the upper surface of base plate 1 and the lower surface of metal layer 23 on the lower surface-side of insulating layer 21 are bonded together by insulating substrate lower bonding material 3 (insulating substrate bonding step), whereby base plate 1 and insulating substrate 2 are bonded together.

Subsequently, case member 4 surrounding insulating substrate 2 is disposed in the outer peripheral region of the upper surface of base plate 1 to which insulating substrate 2 is bonded (case member disposing step). Case member 4 is bonded to base plate 1 using adhesive 5.

Subsequently, pressing member 6 that is in contact with the upper surface of metal layer 22 on the upper surface-side of insulating layer 21 while straddling the facing sides of insulating substrate 2 is disposed in the region surrounded by base plate 1 and case member 4 (pressing member disposing step).

After pressing member 6 is disposed, semiconductor element 7 and terminal 10, or metal layer 22 on the upper surface-side of insulating substrate 2 and terminal 10 are electrically connected to each other using wiring member 9 (wiring member forming step).

After wiring member 9 is formed, filling member 11 is filled in a region surrounded by base plate 1 and case member 4 to seal insulating substrate 2, semiconductor element 7, pressing member 6, and wiring member 9 (filling member filling step). Filling member 11 is filled in a region surrounded by case member 4 and base plate 1 using, for example, a dispenser. As a filling position (filling amount) of filling member 11, filling member 11 is filled up to a position where wiring member 9 is covered (sealed).

After filling member 11 is filled in the region surrounded by base plate 1 and case member 4, defoaming processing is performed in order to remove air bubbles remaining inside filling member 11 (filling member defoaming step). After the defoaming processing of filling member 11, curing processing is performed to cure filling member 11 (filling member curing step). For example, a curing processing condition of filling member 11 is performed under the conditions of 150° C. and 2 hours. In this manner, filling member 11 filled by performing the curing processing is cured.

Through the above main manufacturing steps, semiconductor device 100 in FIG. 1 can be manufactured.

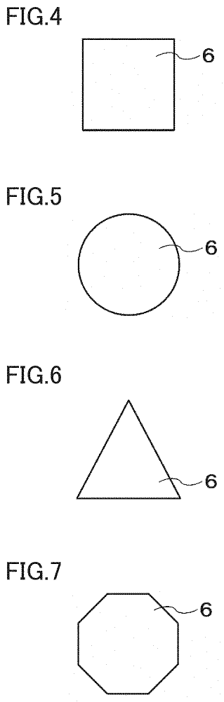

FIGS. 4 to 7 are sectional structure schematic diagrams illustrating the pressing member in the semiconductor device of the first embodiment of the present invention.

In FIG. 1, for example, pressing member 6 has a rod shape. Alternatively, a rod-shaped member can be used as pressing member 6. In FIGS. 4 to 7, for example, a quadrangle, a circle, a triangle, and a hexagon can be used as the sectional shape in the direction perpendicular to the region that is in contact with the upper surface of metal layer 22 of rod-shaped pressing member 6. The sectional shape of pressing member 6 may be any polygonal shape that can be in contact with the upper surface of metal layer 22. Pressing member 6 is in surface contact with the upper surface of metal layer 22 when the sectional shape of pressing member 6 is a polygon such as a quadrangle or a triangle, and a portion in contact with the upper surface of metal layer 22 is a line when the sectional shape of pressing member 6 is a circle. Consequently, when a larger pressing force is required, the sectional shape is not a circle, but a quadrangle, a triangle, or the like that is the sectional shape that can be pressed with a larger area is desirable.

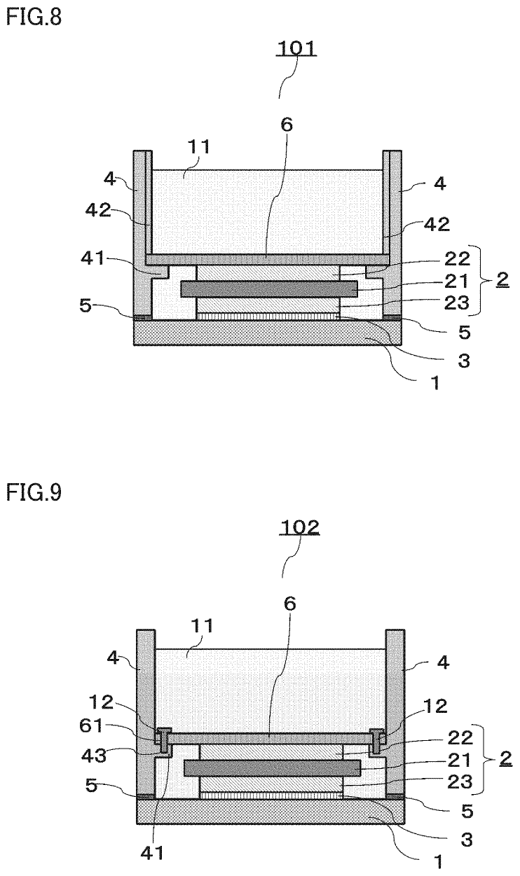

FIGS. 8 to 11 are sectional structure schematic diagrams illustrating another semiconductor device of the first embodiment of the present invention. FIGS. 8 to 11 illustrate a connection (bonding) state between pressing member 6 and case member 4 or a support (holding) state of pressing member 6.

In FIG. 8, in a semiconductor device 101, case member 4 includes a case pedestal 41 that is a case pedestal portion and a slit 42 that is a slit portion in a region where pressing member 6 of case member 4 is disposed. In top view, slit 42 has a recessed shape extending from the inner peripheral side to the outer peripheral side of case member 4 (not illustrated). Pressing member 6 is inserted into slit 42, pressing member 6 is supported by case pedestal 41, and the disposition height of pressing member 6 is adjusted. The pressing force to insulating substrate 2 in the direction of base plate 1 can be applied by setting the height of the upper surface of case pedestal 41 to be the same as or slightly lower than the height of the upper surface of metal layer 22 on the upper surface-side of insulating substrate 2. A length of pressing member 6 may be any length as long as pressing member 6 can be supported (held) between the inner peripheral surfaces of case member 4 at positions where pressing member 6 is disposed. That is, the length of pressing member 6 may be a length slightly longer than the length between the inner peripheral surfaces of case member 4.

In FIG. 9, in a semiconductor device 102, case member 4 includes case pedestal 41 and a screw hole 43 provided in case pedestal 41 in a region where pressing member 6 of case member 4 is disposed. In the connection of pressing member 6 and case member 4, a screw 12 is used to fasten pressing member 6 and case member 4 with screw hole 43 made in case pedestal 41 and a screw hole 61 made in pressing member 6. A depth (length) of screw hole 43 made in case pedestal 41 may be a depth corresponding to the length of the screw or may penetrate pressing member 6. When the depth of screw hole 43 made in case pedestal 41 is deeper than the length of screw 12, the pressing force of insulating substrate 2 in the direction of base plate 1 can be adjusted by a fastening (torque) degree of fastening pressing member 6 to case member 4 by screw 12. The pressing force can be enhanced (increased) by fastening screw 12. A spring may be disposed between the upper surface of pressing member 6 and screw 12, and the pressing force may be applied by the spring (not illustrated).

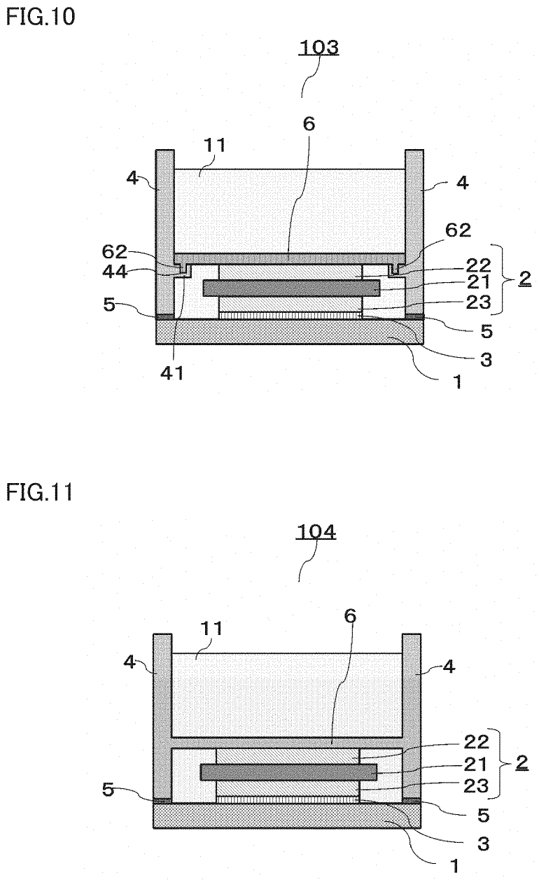

In FIG. 10, in a semiconductor device 103, case member 4 includes case pedestal 41 and a recess 44 provided in case pedestal 41 in a region where pressing member 6 of case member 4 is disposed. In pressing member 6, protrusion 62 is provided at a position corresponding to recess 44 of case pedestal 41. Pressing member 6 and case member 4 are connected by fitting (fitting) protrusion 62 of pressing member 6 and recess 44 of case pedestal 41. In FIG. 10, protrusion 62 is provided in pressing member 6, and recess 44 is provided in case pedestal 41. However, the recess and the protrusion may be formed opposite to each other as long as case member 4 and pressing member 6 can be connected to each other. With the configuration in FIGS. 8 to 11, a portion of pressing member 6 that is in contact with the upper surface of metal layer 22 can be positioned and pressing member 6 can be fixed.

In FIG. 11, in a semiconductor device 104, pressing member 6 and case member 4 are integrally formed. In this case, pressing member 6 protrudes from the inner peripheral surface of case member 4 in a region corresponding to the disposition position of pressing member 6 on the upper surface of metal layer 22 on the upper surface-side of insulating substrate 2. As described above, even when pressing member 6 and case member 4 are integrally formed, insulating substrate 2 can be pressed in the direction of base plate 1 using pressing member 6.

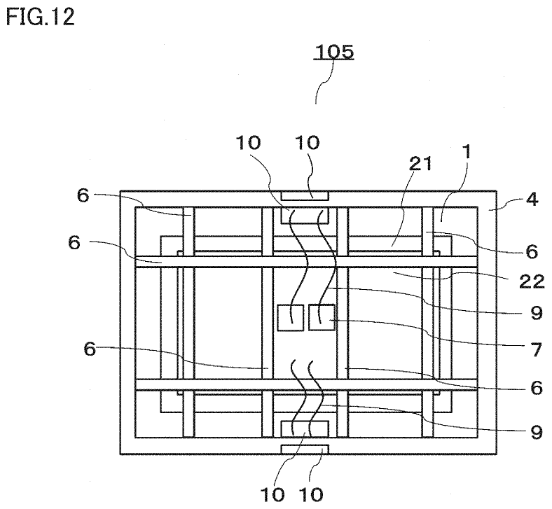

FIG. 12 is a planar structure schematic diagram illustrating another semiconductor device of the first embodiment of the present invention. FIG. 12 is the planar structure schematic diagram illustrating a semiconductor device 105 when viewed from above. In FIG. 12, in a semiconductor device 105, the region where pressing member 6 is in contact with metal layer 22 on the upper surface-side of insulating substrate 2 is the outer peripheral portion of metal layer 22 in addition to a vicinity of semiconductor element 7, and the long side of rectangular pressing member 6 is also in contact with a region (between one corner portion of the side portion and the other corner portion of the side portion) over (along) the entire length in the length direction of the side portion of metal layer 22. Because pressing member 6 is disposed on the outer peripheral portion of metal layer 22, the compressive stress (pressing force) can be also certainly generated at the end portion of insulating substrate lower bonding material 3. As a result, for example, even when the thermal expansion coefficients of insulating substrate 2 and base plate 1 are different from each other, which is a configuration in which the crack or peeling is easily developed at the end of insulating substrate lower bonding material 3, the generation of the crack or peeling can be prevented.

As illustrated in FIG. 12, pressing member 6 may be disposed below wiring member 9 (through the loop of wiring member 9). In such a configuration, wiring member 9 is formed after pressing member 6 is disposed on the upper surface of metal layer 22 on the upper surface-side of insulating substrate 2. Alternatively, pressing member 6 can be divided into a plurality of parts such that pressing member 6 is disposed below wiring member 9, and pressing member 6 can be formed in an assembly type. Furthermore, when pressing members 6 are disposed so as to intersect with each other, at a portion where pressing members 6 intersect with each other, the recess recessed toward the side of intersecting pressing member 6 is formed such that intersecting pressing members 6 are in contact with the upper surface of metal layer 22 on the upper surface-side of insulating substrate 2, whereby the pressing force can be generated in the direction of base plate 1.

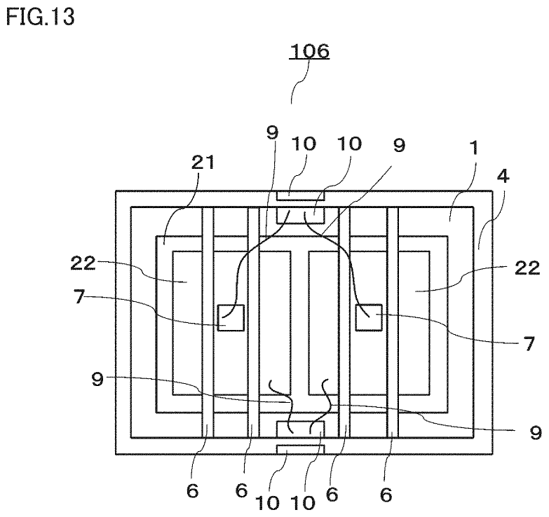

FIG. 13 is a planar structure schematic diagram illustrating another semiconductor device of the first embodiment of the present invention. FIG. 13 is the planar structure schematic diagram illustrating a semiconductor device 106 when viewed from above. In FIG. 13, in semiconductor device 106, two metal layers 22 on the upper surface-side of insulating substrate 2 are disposed. When at least two metal layers 22 are disposed, the upper surface of each metal layer 22 and pressing member 6 are disposed in contact with each other. The disposition of pressing member 6 on the upper surface of each metal layer 22 can be handled by disposing pressing member 6 in the same manner as the case where the number of metal layers 22 is one. As described above, even when a plurality of metal layers 22 are provided, the damage such as the crack or peeling of insulating substrate lower bonding material 3 located below each metal layer 22 can be decreased by disposing pressing member 6 in each metal layer 22.

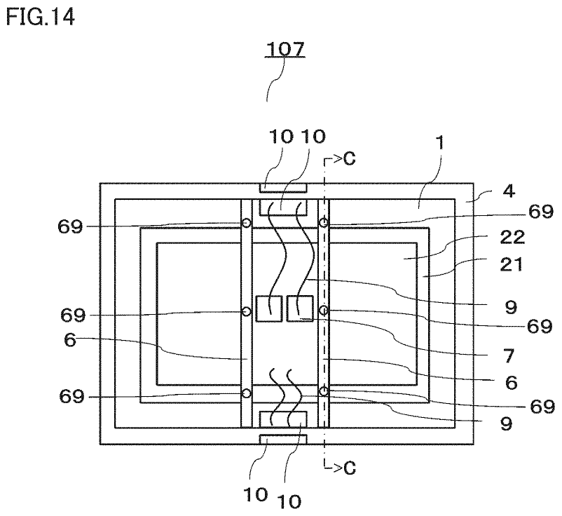

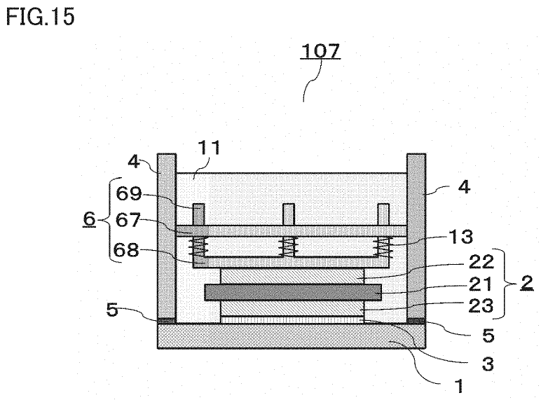

FIG. 14 is a planar structure schematic diagram illustrating another semiconductor device of the first embodiment of the present invention. FIG. 15 is a sectional structure schematic diagram illustrating another semiconductor device of the first embodiment of the present invention. FIG. 14 is the planar structure schematic diagram illustrating a semiconductor device 107 when viewed from above. FIG. 15 is the sectional structure schematic diagram taken along an alternate long and short dash line CC in FIG. 14. In the drawing, in semiconductor device 107, pressing member 6 includes a second beam 68 including a beam 67 and a support portion 69 and a spring 13 that is a spring member. Pressing member 6 includes a plurality of members including beam 67 (first beam) and second beam 68. Beam 67 is fixed to the inner wall of case member 4. Beam 67 has a hole through which support portion 69 passes at a predetermined position. Second beam 68 is a member that transmits the pressing force to insulating substrate 2. In this manner, second beam 68 through which spring 13 passes between metal layer 22 and beam 67 is disposed, so that the pressing force of pressing member 6 can be adjusted by adjusting a gap (interval) between metal layer 22 and beam 67 and a spring constant of spring 13. The pressing force from pressing member 6 to insulating substrate 2 can be uniformly applied using the plurality of springs 13.

In the case of the configuration in FIGS. 14 and 15, pressing member 6 can be manufactured by pressing pressing member 6 with spring member 13 (pressing member pressing step) during the pressing member disposing step.

The number of pressing members 6 can be appropriately selected according to the form of insulating substrate 2, and one or a plurality of pressing members 6 may be used. In addition, pressing member 6 may be fixedly disposed at a predetermined position using an adhesive or the like with no use of the fixing method as described above.

In semiconductor device 100, 101, 102, 103, 104, 105, 106, 107 configured as described above, because pressing member 6 is disposed in contact with the upper surface of metal layer 22 while straddling the facing sides of metal layer 22, entire metal layer 22 is pressed in the direction of base plate 1, thereby generating the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of semiconductor device 100, 101, 102, 103, 104, 105, 106, 107 can be improved.

### Second Embodiment

A second embodiment is different from the first embodiment in that pressing member 6 used in the first embodiment is provided in contact with the upper surface of insulating layer 21 of insulating substrate 2 while straddling the facing sides of insulating layer 21 (insulating substrate 2). In this way, pressing member 6 that is in contact with the upper surface of insulating layer 21 of insulating substrate 2 while straddling the facing sides of insulating layer 21 is formed, so that entire insulating layer 21 is pressed in the direction of base plate 1 to generate the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved. Other points are the same as those in the first embodiment, and the detailed description is omitted.

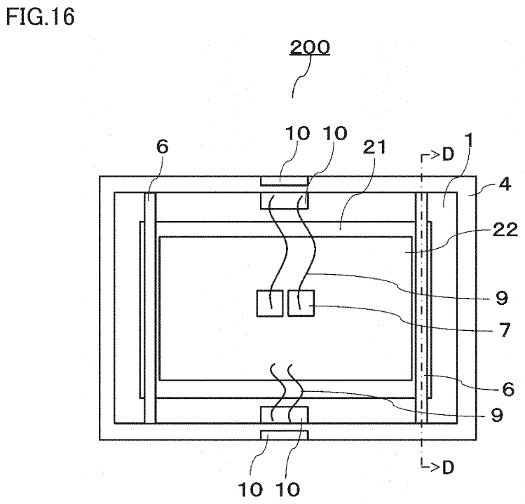

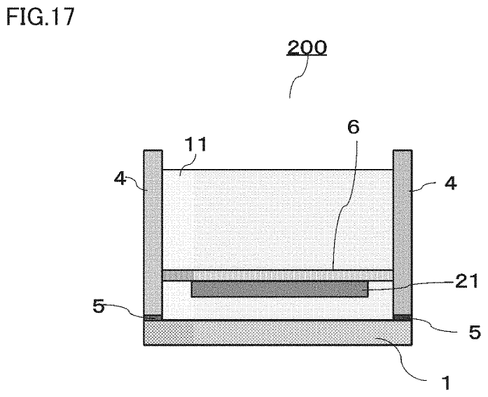

FIG. 16 is a planar structure schematic diagram illustrating a semiconductor device of the second embodiment of the present invention. FIG. 17 is a sectional structure schematic diagram illustrating the semiconductor device of the second embodiment of the present invention. FIG. 16 is the planar structure schematic diagram illustrating a semiconductor device 200 when viewed from above. FIG. 17 is the sectional structure schematic diagram taken along an alternate long and short dash line DD in FIG. 16.

In the drawing, semiconductor device 200 includes base plate 1, insulating substrate 2, insulating substrate lower bonding material 3 which is a bonding material, case member 4, adhesive 5, pressing member 6, semiconductor element 7, semiconductor element lower bonding material 8, wiring member 9, terminal 10, and filling member 11.

In FIG. 16, pressing member 6 is in contact with the inner peripheral surface-side of case member 4. Pressing member 6 is disposed in contact with the upper surface of the outer peripheral portion of insulating layer 21 at the portion exposed from metal layer 22 while straddling the opposite side of insulating layer 21.

In FIG. 17, pressing member 6 is in contact with the upper surface of insulating substrate 2 while straddling (across the facing sides) the opposite sides of insulating layer 21 (insulating substrate 2). In the second embodiment, pressing member 6 is disposed in contact with the upper surface of insulating layer 21. Filling member 11 is disposed on the lower surface-side of insulating layer 21, which is opposite to insulating layer 21 in which pressing member 6 is disposed. Because insulating layer 21 protrudes from metal layers 22, 23, the region where pressing member 6 is not disposed is covered with filling member 11.

As a result, entire insulating substrate 2 is pressed in the direction of base plate 1, so that the compressive stress is generated in the entire inside of insulating substrate lower bonding material 3 that is a bonding material. Accordingly, the generation and development of the crack in insulating substrate lower bonding material 3 or the peeling of insulating substrate lower bonding material 3 is prevented, so that damage to the insulating substrate lower bonding material 3 can be reduced.

The mode used in the first embodiment of FIGS. 8 to 11 can be applied as a method for fixing pressing member 6 to case member 4 of the second embodiment.

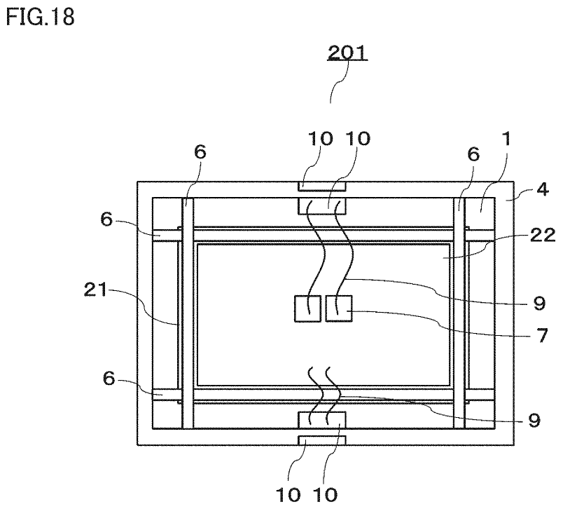

FIG. 18 is a planar structure schematic diagram illustrating another semiconductor device of the second embodiment of the present invention. FIG. 18 is the planar structure schematic diagram illustrating a semiconductor device 201 when viewed from above. In FIG. 18, in semiconductor device 201, the region where pressing member 6 is in contact with the upper surface of insulating layer 21 on the upper surface-side of insulating substrate 2 is not only between one set of facing sides but also the outer peripheral portion of insulating layer 21 between the other facing sides, and the long side of pressing member 6 having the rectangular shape is in contact with the region (between one corner portion of the side portion and the other corner portion of the side portion) over the entire length in the length direction of the side portion of insulating layer 21. Because pressing member 6 is disposed on the outer peripheral portion of insulating layer 21, the compressive stress (pressing force) can be also certainly generated at the end portion of insulating substrate lower bonding material 3. As a result, for example, even when the thermal expansion coefficients of insulating substrate 2 and base plate 1 are different from each other, which is a configuration in which the crack or peeling is easily developed at the end of insulating substrate lower bonding material 3, the generation of the crack or peeling can be prevented.

Furthermore, as in semiconductor device 201 of FIG. 18, pressing member 6 may be disposed below wiring member 9. In such a configuration, wiring member 9 is formed after pressing member 6 is disposed on the upper surface of insulating layer 21 on the upper surface-side of insulating substrate 2. Alternatively, pressing member 6 can be divided into a plurality of parts such that pressing member 6 is disposed below wiring member 9, and pressing member 6 can be formed in an assembly type. When pressing members 6 are disposed so as to intersect with each other, at a portion where pressing members 6 intersect with each other, the recess recessed toward the side of intersecting pressing member 6 is formed such that intersecting pressing members 6 are in contact with the upper surface of insulating layer 21 on the upper surface-side of insulating substrate 2, whereby the pressing force can be generated in the direction of base plate 1.

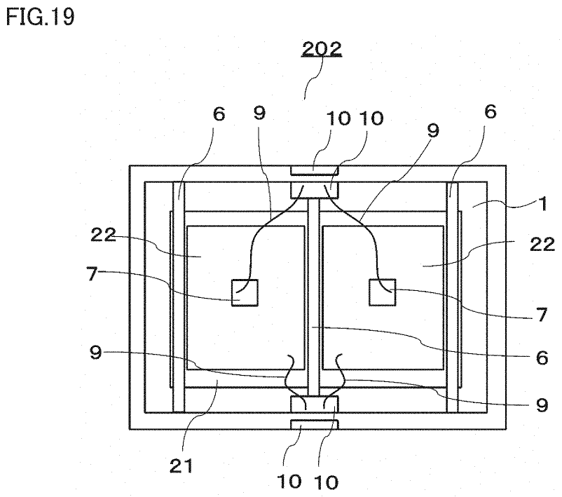

FIG. 19 is a planar structure schematic diagram illustrating another semiconductor device of the second embodiment of the present invention. FIG. 19 is the planar structure schematic diagram illustrating a semiconductor device 202 when viewed from above. In FIG. 19, in semiconductor device 202, two metal layers 22 on the upper surface-side of insulating substrate 2 are disposed. When at least two metal layers 22 are disposed, the upper surface of insulating layer 21 of insulating substrate 2 and pressing member 6 are disposed in contact with each other with each metal layer 22 interposed therebetween. The disposition of pressing member 6 on the upper surface of each insulating layer 21 can be handled by disposing pressing member 6 in the same manner as the case where the number of insulating layers 21 is one. As described above, when the plurality of metal layers 22 are provided, pressing member 6 is disposed on the upper surface of the insulating layer 21 with each metal layer 22 interposed therebetween, so that the damage such as the crack or peeling of insulating substrate lower bonding material 3 located below insulating layer 21 can be decreased.

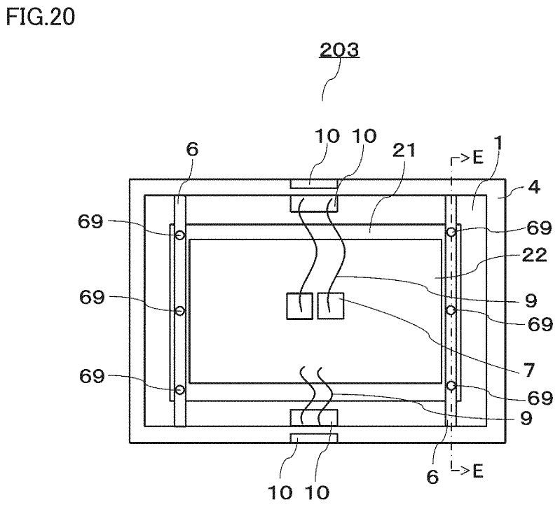

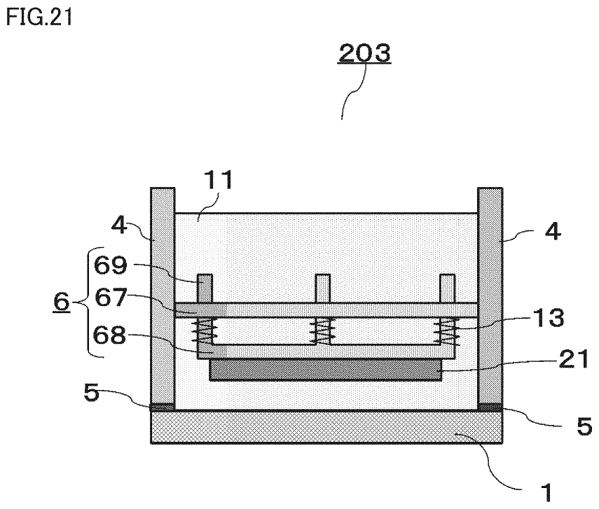

FIG. 20 is a planar structure schematic diagram illustrating another semiconductor device of the second embodiment of the present invention. FIG. 21 is a sectional structure schematic diagram illustrating another semiconductor device of the second embodiment of the present invention. FIG. 20 is the planar structure schematic diagram illustrating a semiconductor device 203 when viewed from above. FIG. 21 is the sectional structure schematic diagram taken along an alternate long and short dash line EE in FIG. 20. In the drawing, in semiconductor device 203, pressing member 6 includes second beam 68 having beam 67 and support portion 69 and spring 13 that is a spring member. Pressing member 6 includes a plurality of members including beam 67 (first beam) and second beam 68. Beam 67 is fixed to the inner wall of case member 4. Beam 67 has a hole through which support portion 69 passes at a predetermined position. In this manner, second beam 68 through which spring 13 passes between insulating layer 21 and beam 67 is disposed, so that the pressing force of pressing member 6 can be adjusted by adjusting the gap (interval) between insulating layer 21 and beam 67 and the spring constant of spring 13. The pressing force from pressing member 6 to insulating substrate 2 can be uniformly applied using the plurality of springs 13.

In semiconductor device 200, 201, 202, 203 configured as described above, because pressing member 6 is disposed in contact with the upper surface of the insulating layer 21 while straddling the facing sides of insulating layer 21, entire insulating layer 21 is pressed in the direction of base plate 1, thereby generating the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of semiconductor device 200, 201, 202, 203 can be improved.

### Third Embodiment

A third embodiment is different from the first embodiment in that pressing member 6 used in the first embodiment protrudes upward from the upper surface of base plate 1, is bent toward the upper surface-side of insulating substrate 2, and is provided in contact with the upper surface of metal layer 22 of insulating substrate 2 while straddling the facing sides of metal layer 22. In this manner, pressing member 6 that protrudes upward from the upper surface of base plate 1, is bent toward the upper surface-side (upper surface direction) of insulating substrate 2, and is in contact with the upper surface of metal layer 22 of insulating substrate 2 while straddling the opposing sides of metal layer 22 is formed, so that entire metal layer 22 is pressed in the direction of base plate 1 to generate the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved. Other points are the same as those in the first embodiment, and the detailed description is omitted.

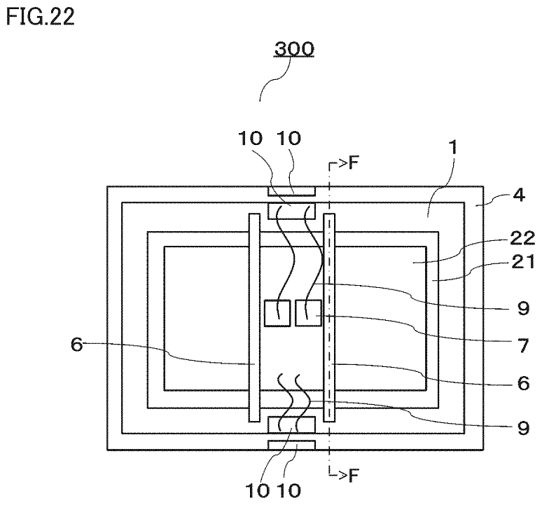

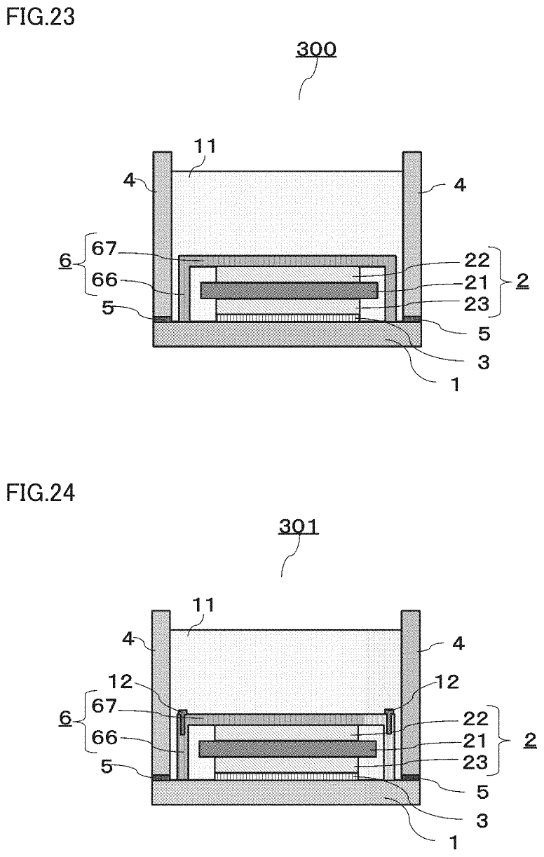

FIG. 22 is a planar structure schematic diagram illustrating a semiconductor device of the third embodiment of the present invention. FIG. 23 is a sectional structure schematic diagram illustrating the semiconductor device of the third embodiment of the present invention. FIG. 22 is the planar structure schematic diagram illustrating a semiconductor device 300 when viewed from above. FIG. 23 is the sectional structure schematic diagram taken along an alternate long and short dash line FF in FIG. 22.

In the drawing, semiconductor device 300 includes base plate 1, insulating substrate 2, insulating substrate lower bonding material 3 which is a bonding material, case member 4, adhesive 5, pressing member 6, semiconductor element 7, semiconductor element lower bonding material 8, wiring member 9, terminal 10, and filling member 11.

In FIGS. 22 and 23, pressing member 6 has a U-shape in which the side of base plate 1 is opened. Pressing member 6 includes a foot 66 and beam 67. Foot 66 of pressing member 6 protrudes upward (toward the upper surface-side of insulating substrate 2) from the upper surface of base plate 1. Beam 67 of pressing member 6 is in contact with the upper surface of metal layer 22 on the upper surface-side of insulating substrate 2 while straddling the facing sides of insulating substrate 2.

Pressing member 6 protrudes upward from the upper surface of base plate 1. A protruding position of pressing member 6 from the upper surface of base plate 1 is an outer peripheral side of insulating substrate 2 spaced inward from the inner peripheral (inner wall) side of case member 4. In addition, pressing member 6 is disposed in contact with the upper surface of metal layer 22 on the upper surface-side of insulating substrate 2. Furthermore, pressing member 6 is bent toward the upper surface-side of insulating substrate 2 in order to be in contact with the upper surface of metal layer 22 on the upper surface-side of insulating substrate 2. In addition, pressing member 6 is disposed while straddling the facing sides of insulating substrate 2 (metal layer 22 on the upper surface-side of insulating substrate 2). Furthermore, pressing member 6 protrudes from the upper surface of base plate 1 and is disposed to surround insulating substrate 2. In addition, the position of pressing member 6 in contact with metal layer 22 on the upper surface-side of insulating substrate 2 is disposed on both sides with semiconductor element 7 disposed on the upper surface of metal layer 22 on the upper surface-side of insulating substrate 2 interposed therebetween. Furthermore, because pressing member 6 protrudes from the upper surface of base plate 1 at a position spaced inward from the inner peripheral surface of case member 4, filling member 11 is also disposed between case member 4 and foot 66 of pressing member 6.

Because pressing member 6 is disposed as described above, entire metal layer 22 on the upper surface-side of insulating substrate 2 is pressed in the direction of base plate 1 by pressing member 6, and the compressive stress is generated in the entire inside of insulating substrate lower bonding material 3 that is the bonding material. As a result, the generation and development of the crack in insulating substrate lower bonding material 3 or the peeling of insulating substrate lower bonding material is prevented, so that the damage due to the thermal stress of insulating substrate lower bonding material 3 can be decreased, and the reliability of semiconductor device 300 can be improved.

FIGS. 24 to 26 are sectional structure schematic diagrams illustrating another semiconductor device of the third embodiment of the present invention. FIGS. 24 to 26 illustrate a connection (joining) state between pressing member 6 and base plate 1.

In FIG. 24, in a semiconductor device 301, pressing member 6 includes beam 67 in contact with the upper surface of metal layer 22 on the upper surface-side of insulating substrate 2 and foot 66 protruding from base plate 1, and beam 67 and foot 66 are fixed by screws 12. Beam 67 of pressing member 6 is fixed to foot 66 of pressing member 6 using screw 12, so that the contact height between beam 67 of pressing member 6 and the upper surface of metal layer 22 can be adjusted by tightening torque of screw 12. The height of the upper end of foot 66 is set to be the same as or slightly lower than the height of the upper surface of metal layer 22 on the upper surface-side of insulating substrate 2, so that the pressing force to insulating substrate 2 in the direction of base plate 1 can be applied.

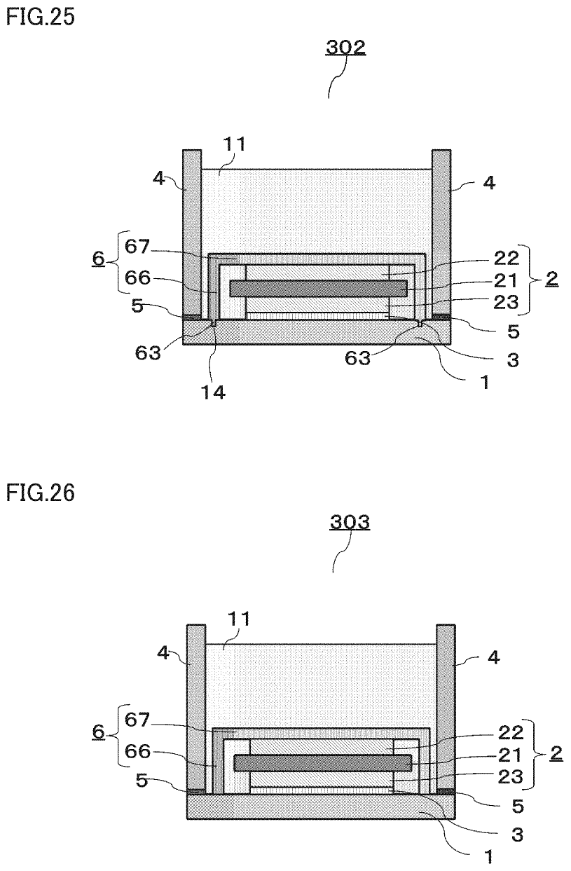

In FIG. 25, in a semiconductor device 302, base plate 1 includes recess 14 in the region where pressing member 6 is disposed on the upper surface of base plate 1. A protrusion 63 is provided at a position corresponding to recess 14 of base plate 1 on the bottom (bottom surface) of foot 66 of pressing member 6. Pressing member 6 and base plate 1 are connected by fitting protrusion 63 of the bottom of foot 66 of pressing member 6 and recess 14 of base plate 1. In FIG. 25, protrusion 63 is provided in the foot portion of pressing member 6, and recess 14 is provided in base plate 1.

However, recess 14 and protrusion 63 may be formed opposite to each other as long as base plate 1 and pressing member 6 can be connected to each other.

In FIG. 26, in a semiconductor device 303, pressing member 6 and base plate 1 are integrally formed. As described above, even when pressing member 6 is integrally formed with base plate 1, insulating substrate 2 can be pressed in the direction of base plate 1 using pressing member 6.

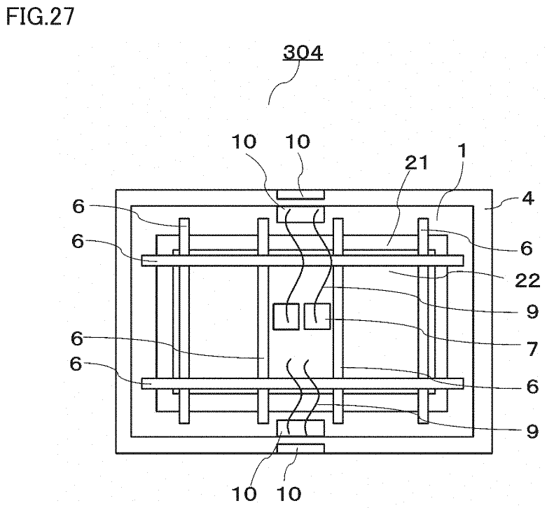

FIG. 27 is a planar structure schematic diagram illustrating another semiconductor device of the third embodiment of the present invention. FIG. 27 is the planar structure schematic diagram illustrating a semiconductor device 304 when viewed from above. In FIG. 27, in a semiconductor device 304, the region where pressing member 6 is in contact with metal layer 22 on the upper surface-side of insulating substrate 2 is the outer peripheral portion of metal layer 22 in addition to the vicinity of semiconductor element 7, and the long side of rectangular pressing member 6 is also in contact with the region (between one corner portion of the side portion and the other corner portion of the side portion) over (along) the entire length in the length direction of the side portion of metal layer 22. Because pressing member 6 is disposed on the outer peripheral portion of metal layer 22, the compressive stress (pressing force) can be also certainly generated at the end portion of insulating substrate lower bonding material 3. As a result, for example, even when the thermal expansion coefficients of insulating substrate 2 and base plate 1 are different from each other, which is a configuration in which the crack or peeling is easily developed at the end of insulating substrate lower bonding material 3, the generation of the crack or peeling can be prevented.

As illustrated in FIG. 27, pressing member 6 may be disposed below wiring member 9. In such a configuration, wiring member 9 is formed after pressing member 6 is disposed on the upper surface of metal layer 22 on the upper surface-side of insulating substrate 2. Alternatively, pressing member 6 can be divided into a plurality of parts such that pressing member 6 is disposed below wiring member 9, and pressing member 6 can be formed in an assembly type. When pressing members 6 are disposed so as to intersect with each other, at a portion where pressing members 6 intersect with each other, the recess recessed toward the side of intersecting pressing member 6 is formed such that intersecting pressing members 6 are in contact with the upper surface of metal layer 22 on the upper surface-side of insulating substrate 2, whereby the pressing force can be generated in the direction of base plate 1.

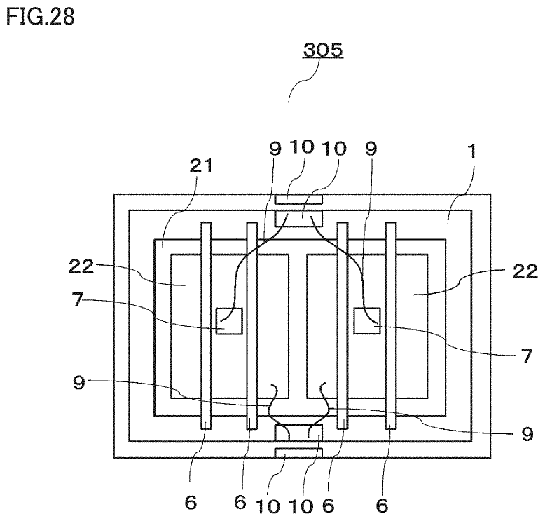

FIG. 28 is a planar structure schematic diagram illustrating another semiconductor device of the third embodiment of the present invention. FIG. 28 is the planar structure schematic diagram illustrating a semiconductor device 305 when viewed from above. In FIG. 28, in semiconductor device 305, two metal layers 22 on the upper surface-side of insulating substrate 2 are disposed. When at least two metal layers 22 are disposed, the upper surface of each metal layer 22 and pressing member 6 are disposed in contact with each other. The disposition of pressing member 6 on the upper surface of each metal layer 22 can be handled by disposing pressing member 6 in the same manner as the case where the number of metal layers 22 is one. As described above, even when the plurality of metal layers 22 are provided, the damage such as the crack or peeling of insulating substrate lower bonding material 3 located below each metal layer 22 can be decreased by disposing pressing member 6 in each metal layer 22.

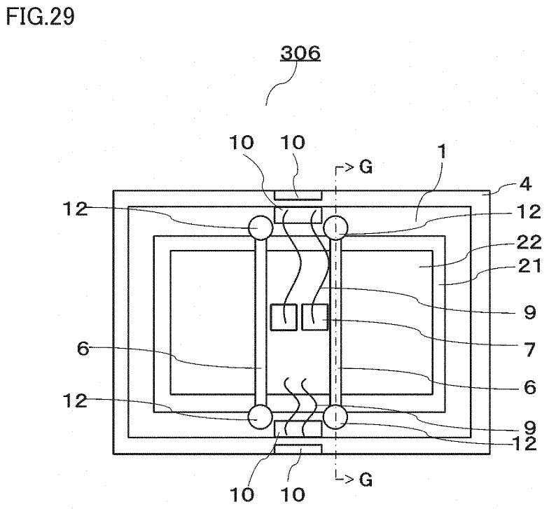

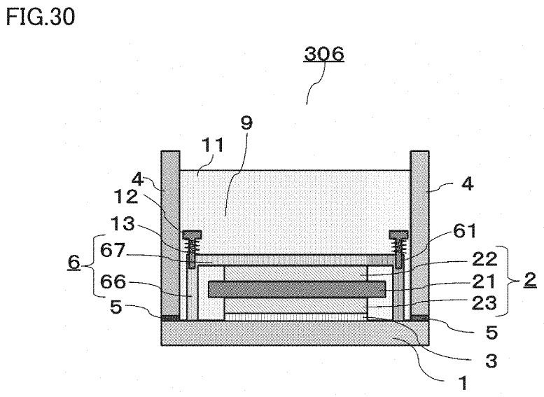

FIG. 29 is a planar structure schematic diagram illustrating another semiconductor device of the third embodiment of the present invention. FIG. 30 is a sectional structure schematic diagram illustrating another semiconductor device of the third embodiment of the present invention. FIG. 29 is the planar structure schematic diagram illustrating a semiconductor device 306 when viewed from above. FIG. 30 is the sectional structure schematic diagram taken along an alternate long and short dash line GG in FIG. 29. In the drawing, semiconductor device 306 includes screw hole 61 extending from the upper surface-side of beam 67 of pressing member 6 to foot 66, screw 12 on the upper surface-side of beam 67 of pressing member 6, and spring 13 through which screw 12 passes. Foot 66 and beam 67 of pressing member 6 are configured as separate members. As described above, because spring 13 is used, the pressing force of pressing member 6 can be adjusted by adjusting the spring constant of spring 13 and the tightening degree of screw 12. The pressing force can be easily adjusted by adjusting the positional relationship between the position of screw 12 and components of semiconductor device 306. In addition, a guide that fixes spring 13 may be provided at a position corresponding to screw hole 61 on the upper surface of pressing member 6 such that spring 13 does not come off.

In semiconductor device 300, 301, 302, 303, 304, 305, 306 configured as described above, pressing member 6 protrudes upward from the upper surface of base plate 1, is bent toward the upper surface-side of insulating substrate 2, and is provided in contact with the upper surface of metal layer 22 of insulating substrate 2 while straddling the facing side of metal layer 22, so that entire metal layer 22 is pressed in the direction of base plate 1 to generate the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of semiconductor device 300, 301, 302, 303, 304, 305, 306 can be improved.

### Fourth Embodiment

A fourth embodiment is different from the third embodiment in that pressing member 6 used in the third embodiment is provided in contact with the upper surface of insulating layer 21 of insulating substrate 2. In this way, pressing member 6 that protrudes upward from the upper surface of base plate 1, is bent toward the upper surface-side of insulating substrate 2, and is in contact with the upper surface of insulating layer 21 of insulating substrate 2 while straddling the facing sides of insulating layer 21 is provided, so that entire insulating layer 21 is pressed in the direction of base plate 1 to generate the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved. Other points are the same as those in the second embodiment, and the detailed description is omitted.

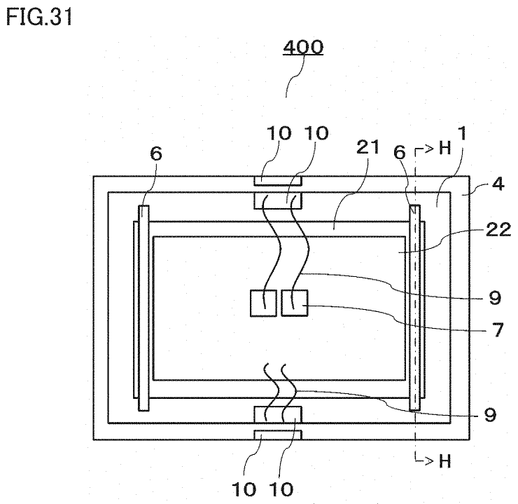

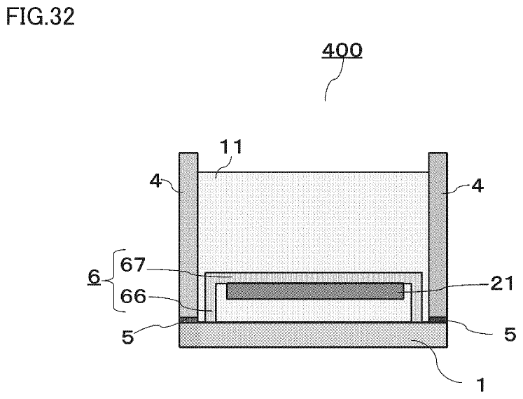

FIG. 31 is a planar structure schematic diagram illustrating a semiconductor device of the fourth embodiment of the present invention. FIG. 32 is a sectional structure schematic diagram illustrating the semiconductor device of the fourth embodiment of the present invention. FIG. 31 is the planar structure schematic diagram illustrating a semiconductor device 400 when viewed from above. FIG. 32 is the sectional structure schematic diagram taken along an alternate long and short dash line HH in FIG. 31. In the drawing, semiconductor device 400 includes base plate 1, insulating substrate 2, insulating substrate lower bonding material 3 which is a bonding material, case member 4, adhesive 5, pressing member 6, semiconductor element 7, semiconductor element lower bonding material 8, wiring member 9, terminal 10, and filling member 11.

In FIG. 31, pressing member 6 is disposed away from the inner peripheral surface of case member 4. Pressing member 6 is also in contact with the region (between one corner portion of the side portion and the other corner portion of the side portion) over the entire length of the side portion of insulating layer 21 at the portion exposed from metal layer 22. Pressing member 6 is disposed in contact with the upper surface of insulating layer 21 while straddling the facing sides of the insulating layer 21.

In FIG. 32, pressing member 6 includes foot 66 protruding upward from the upper surface of base plate 1 and beam 67 that is in contact with the upper surface of insulating layer 21. Filling member 11 is disposed on the lower surface-side of insulating layer 21 that is the opposite surface-side of insulating layer 21 on which pressing member 6 is disposed. Because insulating layer 21 protrudes from metal layers 22, 23, the region where pressing member 6 is not disposed is covered with filling member 11.

In this way, entire insulating substrate 2 is pressed in the direction of base plate 1 by pressing member 6, and the compressive stress is generated in the entire inside of insulating substrate lower bonding material 3 that is the bonding material. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved.

The mode used in the third embodiment of FIGS. 24 to 26 can be applied as a method for fixing pressing member 6 to base plate 1 of the fourth embodiment.

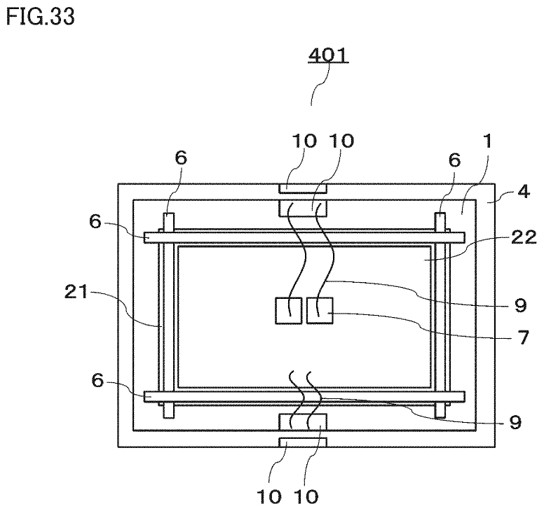

FIG. 33 is a planar structure schematic diagram illustrating another semiconductor device of the fourth embodiment of the present invention. FIG. 33 is the planar structure schematic diagram illustrating a semiconductor device 401 when viewed from above. In FIG. 33, in semiconductor device 401, the region where pressing member 6 is in contact with the upper surface of insulating layer 21 on the upper surface-side of insulating substrate 2 is not only between one set of facing sides but also the outer peripheral portion of insulating layer 21 between the other facing sides, and the long side of pressing member 6 having the rectangular shape is in contact with the region (between one corner portion of the side portion and the other corner portion of the side portion) over the entire length in the length direction of the side portion of insulating layer 21. Because pressing member 6 is disposed on the outer peripheral portion of insulating layer 21, the compressive stress (pressing force) can be also certainly generated at the end portion of insulating substrate lower bonding material 3. As a result, for example, even when the thermal expansion coefficients of insulating substrate 2 and base plate 1 are different from each other, which is a configuration in which the crack or peeling is easily developed at the end of insulating substrate lower bonding material 3, the generation of the crack or peeling of insulating substrate lower bonding material 3 can be prevented.

Furthermore, as in semiconductor device 401 of FIG. 33, pressing member 6 may be disposed below wiring member 9. In such a configuration, wiring member 9 is formed after pressing member 6 is disposed on the upper surface of insulating layer 21 of insulating substrate 2. Alternatively, pressing member 6 can be divided into a plurality of parts such that pressing member 6 is disposed below wiring member 9, and pressing member 6 can be formed in an assembly type. When pressing members 6 are disposed so as to intersect with each other, at a portion where pressing members 6 intersect with each other, the recess recessed toward the side of intersecting pressing member 6 is formed such that intersecting pressing members 6 are in contact with the upper surface of insulating layer 21 of insulating substrate 2, whereby the pressing force can be generated in the direction of base plate 1.

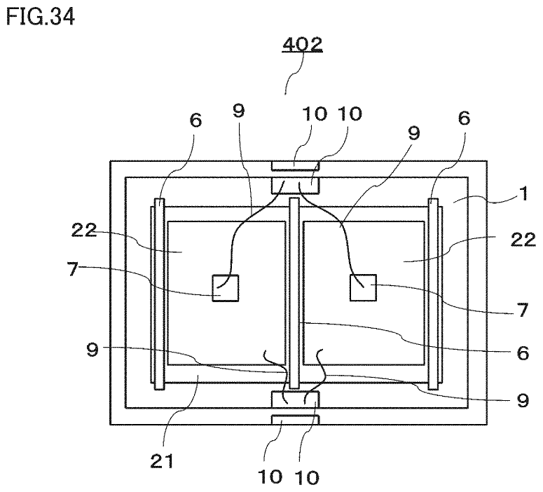

FIG. 34 is a planar structure schematic diagram illustrating another semiconductor device of the fourth embodiment of the present invention. FIG. 34 is the planar structure schematic diagram illustrating a semiconductor device 402 when viewed from above. In FIG. 34, in semiconductor device 402, two metal layers 22 on the upper surface-side of insulating substrate 2 are disposed. When at least two metal layers 22 are disposed, the upper surface of insulating layer 21 of insulating substrate 2 and pressing member 6 are disposed in contact with each other with each metal layer 22 interposed therebetween. The disposition of pressing member 6 on the upper surface of insulating layer 21 can be handled by disposing pressing member 6 on the periphery of metal layer 22 in the same manner as the case where the number of insulating layers 21 is one. As described above, when the plurality of metal layers 22 are provided, pressing member 6 is disposed on the upper surface of the insulating layer 21 with each metal layer 22 interposed therebetween, so that the damage such as the crack or peeling of insulating substrate lower bonding material 3 located below insulating layer 21 can be decreased.

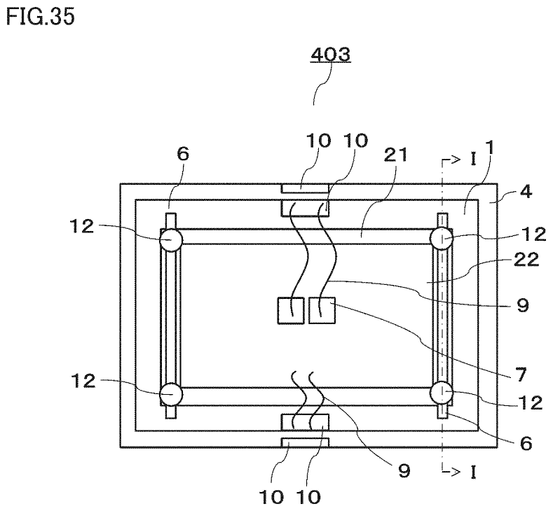

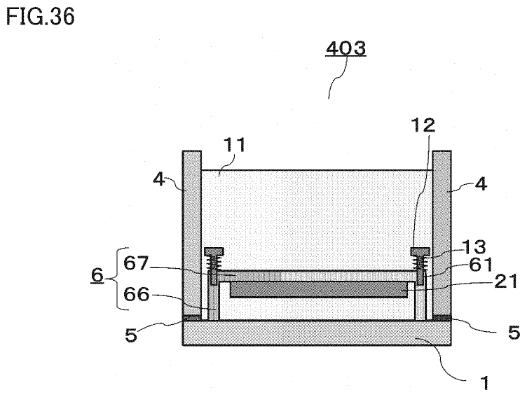

FIG. 35 is a planar structure schematic diagram illustrating another semiconductor device of the fourth embodiment of the present invention. FIG. 36 is a sectional structure schematic diagram illustrating another semiconductor device of the fourth embodiment of the present invention. FIG. 35 is the planar structure schematic diagram illustrating a semiconductor device 403 when viewed from above. FIG. 36 is the sectional structure schematic diagram taken along an alternate long and short dash line II in FIG. 35. In the drawing, semiconductor device 403 includes screw hole 61 extending from the upper surface-side of beam 67 of pressing member 6 to foot 66, screw 12 on the upper surface-side of beam 67 of pressing member 6, and spring 13 through which screw 12 passes. Foot 66 and beam 67 of pressing member 6 are configured as separate members. As described above, because spring 13 is used, the pressing force of pressing member 6 can be adjusted by adjusting the spring constant of spring 13 and the tightening degree of screw 12. The pressing force can be easily adjusted by adjusting the positional relationship between the position of screw 12 and components of semiconductor device 203. In addition, a guide that fixes spring 13 may be provided at a position corresponding to screw hole 61 on the upper surface of pressing member 6 such that spring 13 does not come off

In semiconductor device 400, 401, 402, 403 configured as described above, pressing member 6 protrudes upward from the upper surface of base plate 1, is bent toward the upper surface-side of insulating substrate 2, and is provided in contact with the upper surface of insulating layer 21 of insulating substrate 2 while straddling the facing side of insulating layer 21, so that entire insulating layer 21 is pressed in the direction of base plate 1 to generate the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of semiconductor device 400, 401, 402, 403 can be improved.

### Fifth Embodiment

A fifth embodiment is different from the first, second, third, and fourth embodiments in that the shape of pressing member 6 used in the first, second, third, and fourth embodiments is changed from the rod-shaped member to a plate-shaped member. As described above, even in the case of using plate-shaped pressing member 60, pressing member 60 is formed in contact with the upper surface of metal layer 22 of insulating substrate 2 while straddling the opposite sides of insulating layer 21 or metal layer 22, so that entire metal layer 22 is pressed in the direction of base plate 1 to generate the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved. Other points are the same as those in the first, second, third, and fourth embodiments, and the detailed description is omitted.

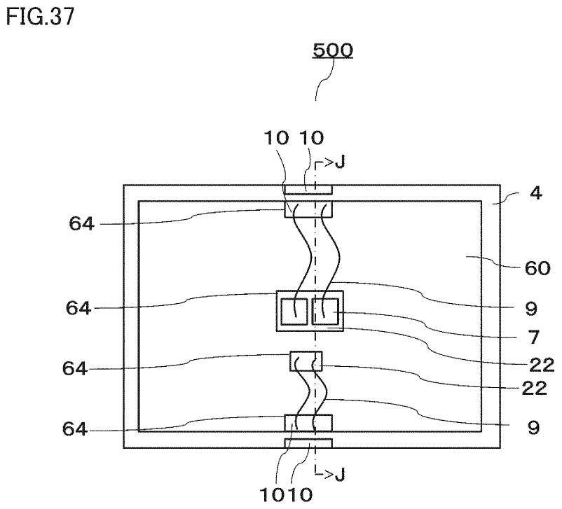

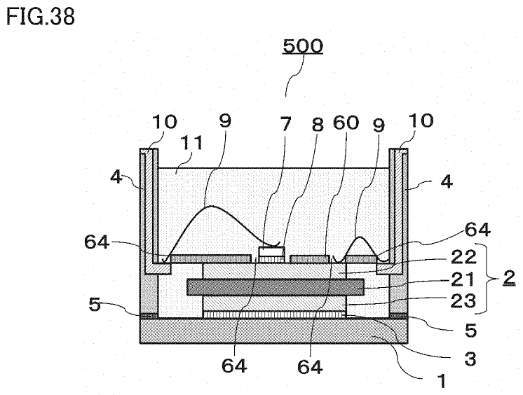

FIG. 37 is a planar structure schematic diagram illustrating a semiconductor device of the fifth embodiment of the present invention. FIG. 38 is a sectional structure schematic diagram illustrating the semiconductor device of the fifth embodiment of the present invention. FIG. 38 is the planar structure schematic diagram illustrating a semiconductor device 500 when viewed from above. FIG. 38 is the sectional structure schematic diagram taken along an alternate long and short dash line JJ in FIG. 37. In the drawing, semiconductor device 500 includes base plate 1, insulating substrate 2, insulating substrate lower bonding material 3 which is a bonding material, case member 4, adhesive 5, a pressing member 60, semiconductor element 7, semiconductor element lower bonding material 8, wiring member 9, terminal 10, and filling member 11.

In FIG. 37, pressing member 60 is disposed in contact with the inner peripheral surface-side of case member 4. The contact portion of pressing member 60 with case member 4 is in contact with the entire circumference (four sides) of the inner peripheral surface of case member 4, but is not necessarily in contact with the entire circumference of the inner peripheral surface of case member 4, and the compressive stress may be generated in insulating substrate 2 in the direction of base plate 1 while pressing member 60 is in contact with the upper surface of metal layer 22. For this reason, when filling member 11 is filled in the region surrounded by base plate 1 and case member 4, a notch (depression) may be provided in pressing member 60 such that filling member 11 is easily filled.

Pressing member 60 includes an opening 64 in a region to which wiring member 9 is connected. The upper surface of semiconductor element 7, the upper surface of the bonding portion of terminal 10, and the upper surface of metal layer 22 are exposed in opening 64 of pressing member 60.

In FIG. 38, pressing member 60 includes openings 64 at positions corresponding to the upper surface of metal layer 22 on the upper surface-side of terminal 10, semiconductor element 7, and insulating substrate 2. Wiring member 9, terminal 10 exposed from opening 64, the upper surface of semiconductor element 7, and the upper surface of metal layer 22 on the upper surface-side of insulating substrate 2 are bonded in opening 64 of pressing member 60. The outer shape of pressing member 60 is larger than the outer shape of insulating substrate 2, and covers the entire surface of insulating substrate 2.

In this way, because pressing member 60 is the plate-shaped member and is provided in contact with the upper surface of metal layer 22 of insulating substrate 2 while straddling the facing sides of insulating substrate 2, entire insulating substrate 2 is pressed in the direction of base plate 1 by pressing member 60 to generate the compressive stress in the entire inside of insulating substrate lower bonding material 3 that is the bonding material. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved.

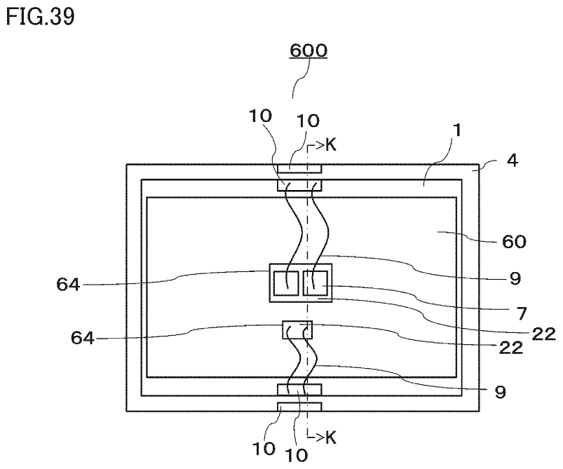

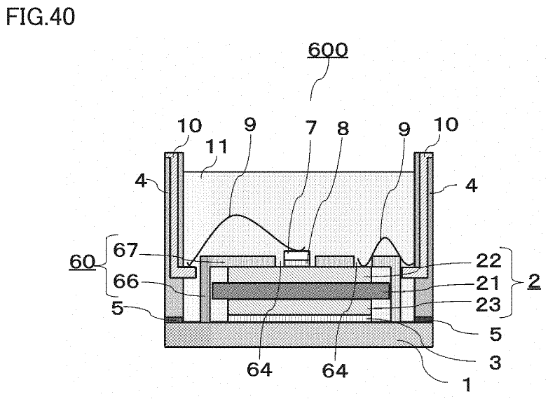

FIG. 39 is a planar structure schematic diagram illustrating another semiconductor device of the fifth embodiment of the present invention. FIG. 40 is a sectional structure schematic diagram illustrating another semiconductor device of the fifth embodiment of the present invention. FIG. 39 is the planar structure schematic diagram illustrating a semiconductor device 600 when viewed from above. FIG. 40 is the sectional structure schematic diagram taken along an alternate long and short dash line KK in FIG. 39. In the drawing, semiconductor device 600 includes base plate 1, insulating substrate 2, insulating substrate lower bonding material 3 which is a bonding material, case member 4, adhesive 5, pressing member 60, semiconductor element 7, semiconductor element lower bonding material 8, wiring member 9, terminal 10, and filling member 11.

In FIG. 39, pressing member 60 is disposed while separated inward from the inner peripheral surface of case member 4. Pressing member 60 includes an opening 64 in a region to which wiring member 9 is connected. The upper surface of semiconductor element 7, the bonding portion of terminal 10, and the upper surface of metal layer 22 are exposed in opening 64 of pressing member 60.

In FIG. 40, pressing member 60 includes openings 64 at positions corresponding to the upper surface of metal layer 22 on the upper surface-side of terminal 10, semiconductor element 7, and insulating substrate 2. Wiring member 9, terminal 10 exposed from opening 64, the upper surface of semiconductor element 7, and the upper surface of metal layer 21 on the upper surface-side of insulating substrate 2 are bonded in opening 64 of pressing member 60. Semiconductor element 7 protrudes upward from the upper surface of pressing member 60 around opening 64. Pressing member 60 includes foot 66 that protrudes upward while being in contact with the upper surface of base plate 1 and beam 67 that is in contact with the upper surface of metal layer 22 on the upper surface-side of insulating substrate 2. Beam 67 of pressing member 60 includes opening 64 at a predetermined position. The foot 66 of pressing member 60 is separated inward from the inner peripheral surface of case member 4 and protrudes from the upper surface of base plate 1. Filling member 11 is disposed between foot 66 of pressing member 60 and the inner peripheral surface of case member 4.

In this way, because pressing member 60 is the plate-shaped member and is provided in contact with the upper surface of metal layer 22 on the upper surface-side of insulating substrate 2 while straddling the facing sides of insulating substrate 2, entire insulating substrate 2 is pressed in the direction of base plate 1 by pressing member 60 to generate the compressive stress in the entire inside of insulating substrate lower bonding material 3 that is the bonding material. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved.

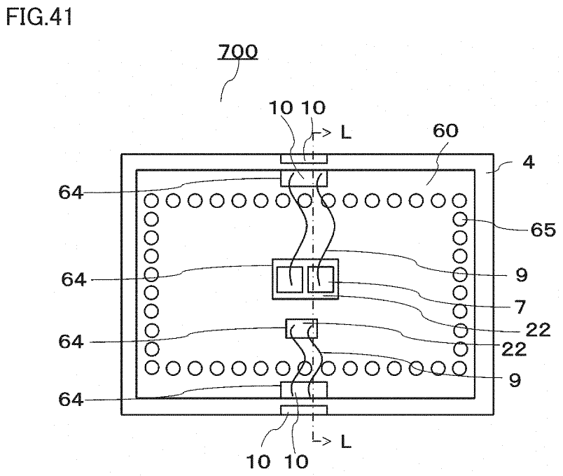

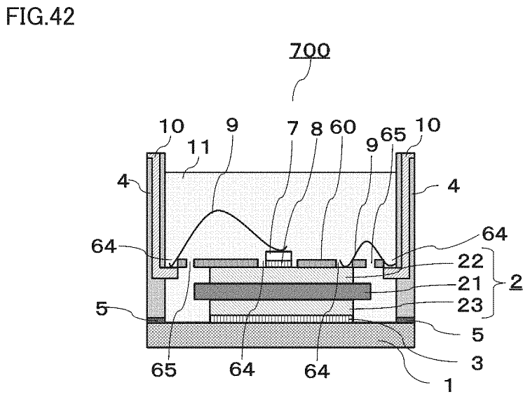

FIG. 41 is a planar structure schematic diagram illustrating a semiconductor device of the fifth embodiment of the present invention. FIG. 42 is a sectional structure schematic diagram illustrating the semiconductor device of the fifth embodiment of the present invention. FIG. 41 is the planar structure schematic diagram illustrating a semiconductor device 700 when viewed from above. FIG. 42 is the sectional structure schematic diagram taken along an alternate long and short dash line LL in FIG. 41. In the drawing, semiconductor device 700 includes base plate 1, insulating substrate 2, insulating substrate lower bonding material 3 which is a bonding material, case member 4, adhesive 5, pressing member 60, semiconductor element 7, semiconductor element lower bonding material 8, wiring member 9, terminal 10, and filling member 11.

In FIG. 41, pressing member 60 is disposed in contact with the inner peripheral surface-side of case member 4. The contact portion of pressing member 60 with case member 4 is in contact with the entire circumference (four sides) of the inner peripheral surface of case member 4, but is not necessarily in contact with the entire circumference of the inner peripheral surface of case member 4, and the compressive stress may be generated in insulating substrate 2 in the direction of base plate 1 while pressing member 60 is in contact with metal layer 22. For this reason, when filling member 11 is filled in the region surrounded by base plate 1 and case member 4, a notch (depression) that makes filling member 11 to flow in the periphery of pressing member 60 may be provided such that filling member 11 is easily filled.

Pressing member 60 includes an opening 64 in a region to which wiring member 9 is connected. The upper surface of semiconductor element 7, the bonding portion of terminal 10, and the upper surface of metal layer 22 are exposed in opening 64 of pressing member 60. In addition, pressing member 60 includes through-holes 65 that are a plurality of through-holes along the outer peripheral region of pressing member 60. Through-hole 65 of pressing member 60 penetrates pressing member 60 to discharge air bubbles generated in filling member 11 filling the region surrounded by base plate 1 and case member 4 to the upper surface-side of pressing member 60. Consequently, the air bubbles remaining in filling member 11 can be reduced.

When the air bubbles exist in filling member 11 at the time of filling filling member 11, the air bubbles serve as a starting point to cause the peeling, and cause partial discharge to lower a withstand voltage of the semiconductor device. For this reason, desirably the air bubbles in filling member 11 is reduced, and in general, defoaming processing is performed before filling and curing filling member 11. At this point, because pressing member 60 is disposed in contact with the inner peripheral surface of case member 4, sometimes the air bubbles are not satisfactorily removed to the outside. However, as illustrated in FIG. 41, when through-hole 65 is made in the outer peripheral region of pressing member 60, the air bubbles are released from the inside to the outside of filling member 11 through through-hole 65, and the peeling of filling member 11 due to the air bubbles is reduced, so that the degradation of the withstand voltage of the semiconductor device can be prevented.

In FIG. 42, pressing member 60 includes openings 64 at positions corresponding to the upper surface of metal layer 22 on the upper surface-side of terminal 10, semiconductor element 7, and insulating substrate 2. Wiring member 9, terminal 10 exposed from opening 64, the upper surface of semiconductor element 7, and the upper surface of metal layer 22 on the upper surface-side of insulating substrate 2 are bonded in opening 64 of pressing member 60. Semiconductor element 7 protrudes upward from the upper surface of pressing member 60 around opening 64. The inside of opening 64 is filled with filling member 11. The outer shape of pressing member 60 is larger than the outer shape of insulating substrate 2, and covers the entire surface of insulating substrate 2. Through-hole 65 through which the air bubbles generated in filling member 11 are guided to the upper surface-side of pressing member 60 is provided in the outer peripheral region of pressing member 60.

Pressing member 60 includes a plurality of through-holes 65 along an outer peripheral region of pressing member 60. Through-hole 65 of pressing member 60 penetrates pressing member 60 to discharge air bubbles generated in filling member 11 filling the region surrounded by base plate 1 and case member 4 to the upper surface-side of pressing member 60. The outer shape of pressing member 60 is larger than the outer shape of insulating substrate 2, and covers the entire surface of insulating substrate 2.

In this way, because pressing member 60 is the plate-shaped member and is provided in contact with the upper surface of metal layer 22 of insulating substrate 2 while straddling the facing sides of insulating substrate 2, entire insulating substrate 2 is pressed in the direction of base plate 1 by pressing member 60 to generate the compressive stress in the entire inside of insulating substrate lower bonding material 3 that is the bonding material. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved. In addition, because through-hole 65 is made in the outer peripheral region of pressing member 60, the air bubbles generated in filling member 11 on the lower surface-side of pressing member 60 can be guided to the upper surface-side of pressing member 60 through through-hole 65, and the peeling of filling member 11 due to the air bubbles is reduced, so that the degradation of the withstand voltage of the semiconductor device can be prevented to improve the reliability of the semiconductor device.

Through-hole 65 made in pressing member 60 may be made in a region other than the outer peripheral region of pressing member 60, and the formation position and the number of through-holes 65 can be arbitrarily set as long as the compressive stress can be generated in insulating substrate 2 in the direction of base plate 1 by the pressing member 60. For example, the shape of through-hole 65 may be a circular shape. However, but the shape is not limited to the circular shape, and may be a polygonal shape such as a quadrangle or a slit shape along the side portion of pressing member 6.

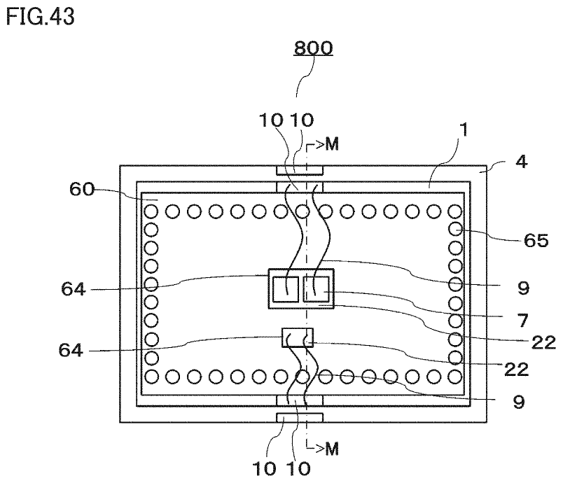

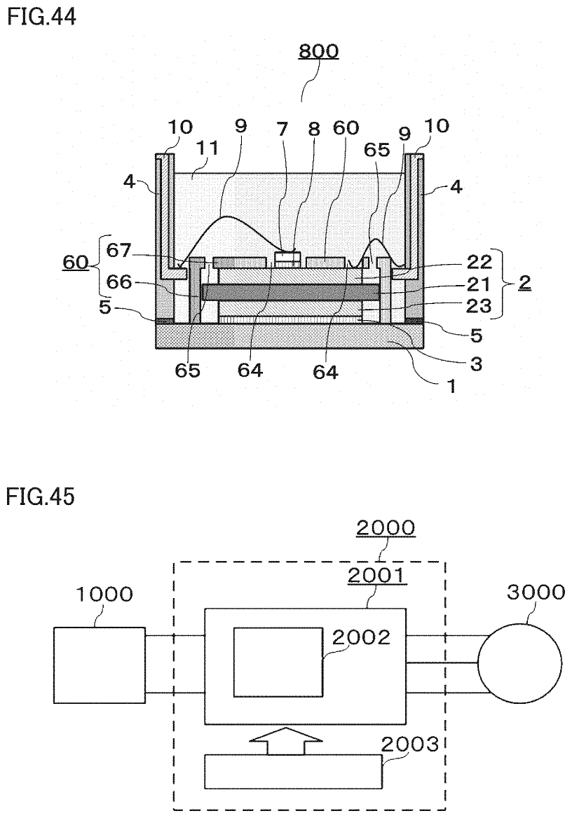

FIG. 43 is a planar structure schematic diagram illustrating a semiconductor device of the fifth embodiment of the present invention. FIG. 44 is a sectional structure schematic diagram illustrating the semiconductor device of the fifth embodiment of the present invention. FIG. 43 is the planar structure schematic diagram illustrating a semiconductor device 800 when viewed from above. FIG. 44 is the sectional structure schematic diagram taken along an alternate long and short dash line MM in FIG. 43. In the drawing, semiconductor device 800 includes base plate 1, insulating substrate 2, insulating substrate lower bonding material 3 which is a bonding material, case member 4, adhesive 5, pressing member 60, semiconductor element 7, semiconductor element lower bonding material 8, wiring member 9, terminal 10, and filling member 11.

In FIG. 43, pressing member 60 is disposed while separated inward from the inner peripheral surface of case member 4. In addition, pressing member 60 includes opening 64 in a region to which wiring member 9 is connected. The upper surface of semiconductor element 7, the bonding portion of terminal 10, and the upper surface of metal layer 22 are exposed in opening 64 of pressing member 60.

Pressing member 60 includes an opening 64 in a region to which wiring member 9 is connected. The upper surface of semiconductor element 7, the bonding portion of terminal 10, and the upper surface of metal layer 22 are exposed in opening 64 of pressing member 60. In addition, pressing member 60 includes through-holes 65 that are a plurality of through-holes along the outer peripheral region of pressing member 60. Through-hole 65 of pressing member 60 penetrates pressing member 60 to discharge air bubbles generated in filling member 11 filling the region surrounded by base plate 1 and case member 4 to the upper surface-side of pressing member 60. Consequently, the air bubbles remaining in filling member 11 can be reduced.

When the air bubbles exist in filling member 11 at the time of filling filling member 11, the air bubbles serve as the starting point, and cause the partial discharge to lower the withstand voltage of the semiconductor device. For this reason, desirably the air bubbles in filling member 11 is reduced, and in general, defoaming processing is performed before filling and curing filling member 11. At this point, because pressing member 60 is disposed in contact with the inner peripheral surface of case member 4, sometimes the air bubbles are not satisfactorily removed to the outside. However, as illustrated in FIG. 41, when through-hole 65 is made in the outer peripheral region of pressing member 60, the air bubbles are released to the outside through through-hole 65, and the peeling of filling member 11 due to the air bubbles is reduced, so that the degradation of the withstand voltage of the semiconductor device can be prevented.

In FIG. 44, pressing member 60 includes openings 64 at positions corresponding to the upper surface of metal layer 22 on the upper surface-side of terminal 10, semiconductor element 7, and insulating substrate 2. Wiring member 9, terminal 10 exposed from opening 64, the upper surface of semiconductor element 7, and the upper surface of metal layer 22 on the upper surface-side of insulating substrate 2 are bonded in opening 64 of pressing member 60. Semiconductor element 7 protrudes upward from the upper surface of pressing member 60 around through-hole 65. The inside of opening 64 is filled with filling member 11.

Pressing member 60 includes foot 66 that protrudes upward while being in contact with the upper surface of base plate 1 and beam 67 that is in contact with the upper surface of metal layer 22 on the upper surface-side of insulating substrate 2. Beam 67 of pressing member 60 includes opening 64 at a predetermined position. The foot 66 of pressing member 60 is separated inward from the inner peripheral surface of case member 4 and protrudes from the upper surface of base plate 1. Filling member 11 is disposed between foot 66 of pressing member 60 and the inner peripheral surface of case member 4. Although filling member 11 is also filled around insulating substrate 2 surrounded by pressing member 60, a slit (opening) may be provided in foot 66 in order to make filling member 11 to flow easily into the periphery of insulating substrate 2 from the outer peripheral surface (side surface) side of foot 66 of pressing member 60.

Pressing member 60 includes a plurality of through-holes 65 along an outer peripheral region of pressing member 60. Through-hole 65 of pressing member 60 penetrates pressing member 60 to discharge air bubbles generated in filling member 11 filling the region surrounded by base plate 1 and case member 4 to the upper surface-side of pressing member 60. The outer shape of pressing member 60 is larger than the outer shape of insulating substrate 2, and covers the entire surface of insulating substrate 2.

In this way, because pressing member 60 is the plate-shaped member and is provided in contact with the upper surface of metal layer 22 of insulating substrate 2 while straddling the facing sides of insulating substrate 2, entire insulating substrate 2 is pressed in the direction of base plate 1 by pressing member 60 to generate the compressive stress in the entire inside of insulating substrate lower bonding material 3 that is the bonding material. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of the semiconductor device can be improved. In addition, because through-hole 65 is made in the outer peripheral region of pressing member 60, the air bubbles generated in filling member 11 on the lower surface-side of pressing member 60 can be guided to the upper surface-side of pressing member 60 through through-hole 65, and the peeling of filling member 11 due to the air bubbles is reduced, so that the degradation of the withstand voltage of the semiconductor device can be prevented to improve the reliability of the semiconductor device.

Through-hole 65 made in pressing member 60 may be made in a region other than the outer peripheral region, and the formation position and the number of through-holes 65 can be arbitrarily set as long as the compressive stress can be generated in insulating substrate 2 in the direction of base plate 1 by the pressing member 60.

The mode used in the first embodiment of FIGS. 8 to 11 and the same mode used in the third embodiment of FIGS. 24 to 26 can be applied as a method for fixing pressing member 60 of the fifth embodiment to case member 4 or base plate 1. When these fixing methods are applied to the fifth e embodiment, pressing member 60 may not have the same configuration as case member 4 or base plate 1 over the entire circumference, and may be partially applied as long as pressing member 60 can be supported by case member 4 or base plate 1.

Furthermore, the number of pressing members 60 can be appropriately selected according to the form of insulating substrate 2, and may be one, or a plurality of pressing members 60 divided into a plurality of sheets may be disposed.

In semiconductor device 500, 600, 700, 800 configured as described above, because plate-shaped pressing member 60 is provided in contact with the upper surface of metal layer 22 of insulating substrate 2 while straddling the opposite sides of insulating substrate 2, entire metal layer 22 is pressed in the direction of base plate 1, thereby generating the compressive stress in the entire inside of insulating substrate lower bonding material 3. As a result, the generation and development of the crack in insulating substrate lower bonding material 3 or the peeling of insulating substrate lower bonding material 3 is prevented, so that the damage due to the thermal stress of insulating substrate lower bonding material 3 can be decreased, and the reliability of semiconductor device 500, 600, 700, 800 can be improved.

In semiconductor device 700, 800, because through-hole 65 is made in the outer peripheral region of plate-shaped pressing member 60, the air bubbles generated inside filling member 11 on the lower surface-side of pressing member 60 are guided to the upper surface-side of pressing member 60 through through-hole 65, and the peeling of filling member 11 due to the air bubbles is reduced, so that the degradation of the withstand voltage can be prevented to improve the reliability of semiconductor device 700, 800.

### Sixth Embodiment

In a sixth embodiment, the semiconductor device according to any one of the first to fifth embodiments described above is applied to a power conversion device. Although the present invention is not limited to a specific power conversion device, the case that the present invention is applied to a three-phase inverter will be described below as the sixth embodiment.

FIG. 45 is a block diagram illustrating a configuration of a power conversion system to which the power conversion device of the sixth embodiment of the present invention is applied.

The power conversion system in FIG. 45 includes a power supply 1000, a power conversion device 2000, and a load 3000. Power supply 1000 is a DC power supply, and supplies DC power to power conversion device 2000. Power supply 1000 can be configured by various components. For example, power supply 1000 can be configured by a DC system, a solar cell, and a storage battery, or may be configured by a rectifier circuit connected to an AC system, an AC/DC converter, and the like. Power supply 1000 may be constructed with a DC-DC converter that converts the DC power output from the DC system into predetermined power.

Power conversion device 2000 is a three-phase inverter connected between power supply 1000 and load 3000, converts the DC power supplied from power supply 1000 into AC power, and supplies the AC power to load 3000. As illustrated in FIG. 45, power conversion device 2000 includes a main conversion circuit 2001 that converts the DC power input from power supply 1000 into the AC power and outputs the AC power and a control circuit 2003 that outputs a control signal controlling main conversion circuit 2001 to main conversion circuit 2001.

Load 3000 is a three-phase motor driven by the AC power supplied from power conversion device 2000. Load 3000 is not limited to a specific application, but is a motor mounted on various electric appliances. For example, load 3000 is used as a hybrid car, an electric car, a rail vehicle, an elevator, or a motor for an air conditioner.

Details of power conversion device 2000 will be described below. Main conversion circuit 2001 includes a switching element and a reflux diode built in a semiconductor device 2002 (not illustrated), converts the DC power supplied from power supply 1000 into the AC power by switching of the switching element, and supplies the AC power to load 3000. Although there are various specific circuit configurations of main conversion circuit 2001, main conversion circuit 2001 according to the sixth embodiment is a two-level three-phase full bridge circuit, and can be configured by six switching elements and six reflux diodes connected in anti-parallel to the respective switching elements. Main conversion circuit 2001 includes semiconductor device 2002 corresponding to any one of the first to fifth embodiments incorporating each switching element, each reflux diode, and the like. Six switching elements are connected in series in every two switching elements to constitute upper and lower arms, and each upper and lower arm constitutes each phase (U-phase, V-phase, W-phase) of the full bridge circuit. An output terminal of each of the upper and lower arms, namely, three output terminals of main conversion circuit 2001 are connected to load 3000.

Main conversion circuit 2001 includes a drive circuit (not illustrated) that drives each switching element. The drive circuit may be built in semiconductor device 2002, or may be configured to include a drive circuit separately from semiconductor device 2002. The drive circuit generates a drive signal driving the switching element of main conversion circuit 2001, and supplies the drive signal to the control electrode of the switching element of main conversion circuit 2001. Specifically, the drive signal turning on the switching element and the drive signal turning off the switching element are output to the control electrode of each switching element according to the control signal from control circuit 2003 (described later). The drive signal is a voltage signal (ON signal) greater than or equal to a threshold voltage of the switching element when the switching element is maintained in an ON state, and the drive signal is a voltage signal (OFF signal) equal to or smaller than the threshold voltage of the switching element when the switching element is maintained in an OFF state.

Control circuit 2003 controls the switching elements of main conversion circuit 2001 such that the desired power is supplied to load 3000. Specifically, time (ON time) during which each switching element of main conversion circuit 2001 is to be turned on is calculated based on the power to be supplied to load 3000. For example, main conversion circuit 2001 can be controlled by PWM control that modulates the ON time of the switching element according to the voltage to be output. In addition, a control command (control signal) is output to the drive circuit included in main conversion circuit 2001 such that an ON signal is output to the switching element to be turned on at each time point and such that an OFF signal is output to the switching element to be turned off at each time point. The drive circuit outputs the ON signal or the OFF signal as the drive signal to the control electrode of each switching element according to the control signal.

In the power conversion device according to the sixth embodiment configured as described above, the reliability can be improved because the semiconductor device according to the first or fifth embodiment is applied as semiconductor device 2002 of main conversion circuit 2001.

Although the example in which the present invention is applied to the two-level three-phase inverter is described in the sixth embodiment, the present invention is not limited to the sixth embodiment, but can be applied to various power conversion devices. In the sixth embodiment, the two-level power conversion device is used. However, a three-level or multi-level power conversion device may be used, or the present invention may be applied to a single-phase inverter when the power is supplied to a single-phase load. In addition, the present invention can also be applied to a DC/DC converter, an AC/DC converter, or the like when the power is supplied to a DC load or the like.

In addition, the power conversion device to which the present invention is applied is not limited to the case where the load described above is the electric motor, but can also be used as, for example, a power supply device for an electric discharge machine, a laser beam machine, an induction heating cooker, or a non-contact power feeding system, and can also be used as a power conditioner for a solar power generation system, a power storage system, or the like.

In particular, when SiC is used as semiconductor element 7, the power semiconductor element is operated at a higher temperature as compared with the case of Si in order to utilize the characteristic of the power semiconductor element. In the semiconductor device on which a SiC device is mounted, because higher reliability is required, the merit of the present invention of realizing the highly reliable semiconductor device is more effective.

It should be considered that the above-described embodiments are an example in all respects and not restrictive. The scope of the present invention is indicated by the claims rather than the scope of the above-described embodiments, and includes all modifications within the meaning and scope equivalent to the claims. In addition, the invention may be formed by appropriately combining a plurality of constituent elements disclosed in the above embodiment.

### REFERENCE SIGNS LIST

1: base plate, 2: insulating substrate, 3: insulating substrate lower bonding material, 4: case member, 5: adhesive, 6, 60: pressing member, 7: semiconductor element, 8: Semiconductor element lower bonding material, 9: wiring member, 10: terminal, 11: filling member, 12: screw, 13: spring, 14, 44: recess, 21: insulating layer, 22, 23: metal layer, 41: case pedestal, 42: slit, 43, 61: screw hole, 62, 63: protrusion, 64: opening, 65: through-hole, 66: foot, 67: beam, 68: second beam, 69: support portion, 100, 101, 102, 103, 104, 105, 106, 107, 200, 201, 202, 203, 300, 301, 302, 303, 304, 305, 306, 400, 401, 402, 403, 500, 600, 700, 800, 2002: semiconductor device, 1000: power supply, 2000: power conversion device, 2001: main conversion circuit, 2003: control circuit, 3000: load

1. A semiconductor device comprising:
a base plate;
an insulating substrate having a flat lower surface, and including an insulating layer, and metal layers provided on an upper surface and a lower surface of the insulating layer;
a bonding material bonding an upper surface of the base plate and a lower surface of the metal layer on a lower surface-side of the insulating layer;
a case member disposed on the upper surface of the base plate to surround the insulating substrate; and
a pressing member that is disposed in a region surrounded by the base plate and the case member, straddles facing sides of the insulating substrate, and is in contact with an upper surface, from one to the other of the facing sides, of the insulating substrate.

2. The semiconductor device according to claim 1, wherein the pressing member is disposed in contact with an inner periphery of the case member.

3. The semiconductor device according to claim 1, wherein the pressing member is in contact with the upper surface of the base plate.

4. The semiconductor device according to claim 1, wherein the pressing member has a rod shape and is in contact with an upper surface of the metal layer on an upper surface-side of the insulating layer or the upper surface of the insulating layer.

5. The semiconductor device according to claim 1, wherein the pressing member has a circular or polygonal sectional shape.

6. The semiconductor device according to claim 1, wherein the pressing member is disposed along a side portion of the metal layer or the insulating layer at an outer peripheral portion of the metal layer or the insulating layer.

7. The semiconductor device according to claim 1, wherein the pressing member is a plate-shaped member that covers the upper surface of the insulating substrate, and is in contact with an upper surface of the metal layer on an upper surface-side of the insulating layer.

8. The semiconductor device according to claim 1, wherein a plurality of the pressing members are disposed.

9. The semiconductor device according to claim 1, wherein the pressing member is an elastic body.

10. The semiconductor device according to claim 1, wherein the pressing member includes a spring member.

11. The semiconductor device according to claim 7, wherein a through-hole is formed in the pressing member.

12. The semiconductor device according to claim 1, wherein a pedestal portion that supports the pressing member is provided in the case member.

13. The semiconductor device according to claim 1, wherein a slit portion in which the pressing member is disposed is provided in the case member.

14. The semiconductor device according to claim 1, wherein the pressing member is formed integrally with the case member or the base plate.

15. A method for manufacturing a semiconductor device, the method comprising:
preparing a base plate;
preparing an insulating substrate in which metal layers are provided on an upper surface and a lower surface of an insulating layer, the insulating substrate having a flat lower surface;
bonding an upper surface of the base plate and a lower surface of the metal layer on a lower surface-side of the insulating layer with a bonding material;
disposing a case member that is in contact with the upper surface of the base plate to surround the insulating substrate; and
disposing a pressing member that is disposed in a region surrounded by the base plate and the case member, straddles facing sides of the insulating substrate, and is in contact with an upper surface, from one to the other of the facing sides, of the insulating substrate.

16. The method for manufacturing a semiconductor device according to claim 15, wherein the disposing a pressing member includes pressing the pressing member with a spring member.

17. A power conversion device comprising:
a main conversion circuit including the semiconductor device according to claim 1, to convert and output input power; and
a control circuit to output, to the main conversion circuit, a control signal controlling the main conversion circuit.

18. The semiconductor device according to claim 1, wherein a semiconductor element is disposed on an upper surface of the metal layer on an upper surface-side of the insulating layer, and the pressing member is in contact with the upper surface of the metal layer on the upper surface-side of the insulating layer on which the semiconductor element is disposed.

19. The method for manufacturing a semiconductor device according to claim 15, wherein the pressing member is in contact with an upper surface of the metal layer on an upper surface-side of the insulating layer, or in contact with the upper surface of the insulating layer.

20. The method for manufacturing a semiconductor device according to claim 15, wherein a semiconductor element is disposed on an upper surface of the metal layer on an upper surface-side of the insulating layer, and the pressing member is in contact with the upper surface of the metal layer on the upper surface-side of the insulating layer on which the semiconductor element is disposed.
